(19) United States
(12) Patent Application Publication
(10) Pub. No.: US 2025/0216469 A1
(43) Pub. Date: Jul. 3, 2025

(54) ELECTRONIC APPARATUS, CONTROL METHOD, COMPUTER PROGRAM, AND STORAGE MEDIUM

(71) Applicant: Panasonic Intellectual Property Management Co., Ltd., Osaka (JP)

(72) Inventors: Yoshihiro KANEKO, Osaka (JP); Keiichiro YOHARA, Osaka (JP); Yuya AKAI, Osaka (JP); Daiki KASAHARA, Osaka (JP); Masato TANAKA, Aichi (JP)

(73) Assignee: Panasonic Intellectual Property Management Co., Ltd., Osaka (JP)

(21) Appl. No.: 19/079,541

(22) Filed: Mar. 14, 2025

Related U.S. Application Data
(63) Continuation of application No. PCT/JP2023/032156, filed on Sep. 1, 2023.

(30) Foreign Application Priority Data
Sep. 14, 2022 (JP) 2022-146509

(51) Int. Cl. G01R 31/387; G06F 9/451; H04N 7/15

(52) U.S. Cl. CPC G01R 31/387; G06F 9/451; H04N 7/15

(57) ABSTRACT

An electronic apparatus includes a controller, a storage, and a battery that supplies power to the controller and the storage. The controller acquires conference information related to a web conference. The conference information includes information for specifying an application used in the web conference, a date and time of the web conference, and information related to a conference place or a conference participant. The controller determines information related to a use function or a use apparatus used in the application of the web conference based on the acquired conference information, calculates predicted power consumption consumed in the web conference based on the determined information related to the use function or the use apparatus, and calculates a change in the remaining capacity of the battery based on the calculated predicted power consumption and remaining capacity of the battery.

### TECHNICAL FIELD

The present disclosure relates to an electronic apparatus, a control method, a computer program, and a storage medium.

### BACKGROUND ART

The usable time of an electronic apparatus to which the driving power is supplied from the battery is greatly related to the power consumption when the electronic apparatus is used. By predicting the power consumption, it is possible to determine whether or not the remaining capacity of the battery becomes insufficient. PTL 1 describes an information processing apparatus that obtains a consumption value of a battery related to a conference based on the conference date and time data. The information processing apparatus described in PTL 1 displays a message prompting charging of a battery or a message prompting printing of document data to be browsed at a conference based on the predicted battery consumption value for the conference.

### CITATION LIST

### Patent Literature

PTL 1: Unexamined Japanese Patent Publication No. 2018-117426

### SUMMARY OF THE INVENTION

However, the technique described in PTL 1 still has room for improvement in terms of prediction of power consumption by a conference.

An object of the present disclosure is to provide an electronic apparatus, a control method, a computer program, and a storage medium capable of more accurately calculating predicted power consumption by a web conference.

In order to solve the above-described problems, the present disclosure provides an electronic apparatus, a control method, a computer program, and a storage medium.

An electronic apparatus according to one aspect of the present disclosure includes a controller, a storage that stores an instruction executed by the controller, and a battery that supplies power to the controller and the storage. The controller acquires conference information related to a web conference. The conference information includes information for specifying an application used in the web conference, a date and time of the web conference, and information related to a conference place or a conference participant. The controller determines information related to a use function or a use apparatus used in the application of the web conference based on the acquired conference information. The controller calculates predicted power consumption consumed in the web conference based on the determined information related to the use function or the use apparatus. The controller calculates a change in the remaining capacity of the battery based on the calculated predicted power consumption and the remaining capacity of the battery.

In addition, a control method for controlling an electronic apparatus including a battery of another aspect according to the present disclosure, the control method includes steps of: acquiring conference information related to a web conference, in which the conference information includes information for specifying an application used in the web conference, a conference date and time of the web conference, and information related to a conference place or a conference participant; and determining information related to a use function or a use apparatus used in an application of the web conference based on the acquired conference information; calculating predicted power consumption consumed in the web conference based on the determined information related to the use function or the use apparatus; and calculating a change in remaining capacity of the battery based on the calculated predicted power consumption and the remaining capacity of the battery.

In addition, a computer program of another aspect according to the present disclosure is a computer program for causing an electronic apparatus to execute the control method described above.

In addition, a storage medium of another aspect according to the present disclosure is a non-transitory computer-readable storage medium in which a computer program is stored. When the computer program is executed by a processor, the above-described control method is implemented.

In the present disclosure, according to the electronic apparatus, the control method, the computer program, and the storage medium, the predicted power consumption by the web conference can be calculated more accurately.

### BRIEF DESCRIPTION OF THE DRAWINGS

FIG. 1 is a block diagram illustrating an example of a configuration of an electronic apparatus according to a first exemplary embodiment.

FIG. 2 is a flowchart of an example of a control method in the first embodiment.

FIG. 3 is an example of conference information in the first exemplary embodiment.

FIG. 4 is an example of use conditions in the first exemplary embodiment.

FIG. 5 is an example of a comparison table in the first exemplary embodiment.

FIG. 6 is a flowchart of an example of a control method in a second exemplary embodiment.

FIG. 7 is an example of timing at which the remaining capacity of a battery becomes insufficient in the second exemplary embodiment.

FIG. 8A is an example of a movement schedule in the second exemplary embodiment.

FIG. 8B is another example of the movement schedule in the second exemplary embodiment.

FIG. 9 is an example of a notification message in the second exemplary embodiment.

FIG. 10 is a flowchart of an example of the control method in a third exemplary embodiment.

FIG. 11 is an example of a graphical user interface (GUI) according to the third exemplary embodiment.

FIG. 12 is a flowchart of another example of the control method in the third exemplary embodiment.

FIG. 13A is an example of a schedule before updating in the third exemplary embodiment.

FIG. 13B is an example of an updated schedule in the third exemplary embodiment.

FIG. 14 is a flowchart of an example of the control method in a fourth exemplary embodiment.

FIG. 15 is a flowchart of another example of the control method in the fourth exemplary embodiment.

FIG. 16 is a flowchart of an example of the control method in a fifth exemplary embodiment.

FIG. 17 is a flowchart of an example of step S540 in the fifth exemplary embodiment.

### DESCRIPTION OF EMBODIMENT

First, various aspects of an electronic apparatus, a control method, a computer program, and a storage medium will be described.

An electronic apparatus of a first aspect according to the present disclosure includes a controller, a storage that stores an instruction executed by the controller, and a battery that supplies power to the controller and the storage. The controller acquires conference information related to a web conference. The conference information includes information for specifying an application used in the web conference, a date and time of the web conference, and information related to a conference place or a conference participant. The controller determines information related to a use function or a use apparatus used in the application of the web conference based on the acquired conference information. The controller calculates predicted power consumption consumed in the web conference based on the determined information related to the use function or the use apparatus. The controller calculates a change in the remaining capacity of the battery based on the calculated predicted power consumption and the remaining capacity of the battery.

According to such a configuration, the electronic apparatus can analyze the conference information and automatically determine information related to the use function or the use apparatus used in the application of the web conference. By considering use conditions of the application of the web conference such as the use function or the use apparatus, predicted power consumption consumed in the web conference can be calculated more accurately. As a result, the overall power consumption of the electronic apparatus can be predicted more accurately, and the application using the prediction result of the power consumption can be more appropriately performed.

In the electronic apparatus of the second aspect according to the present disclosure, in the first aspect, the controller may acquire at least part of the conference information from a schedule of a user in which a schedule of the web conference is registered, from the web conference guide mail, or from a user input.

In the electronic apparatus of a third aspect according to the present disclosure, in the first aspect or the second aspect, the conference information may include at least one of information for specifying an application used in the web conference, a conference title, a conference type, a conference date and time, a conference place, a conference participant, and a conference organizer.

In the electronic apparatus of a fourth aspect according to the present disclosure, in any one of the first aspect to the third aspect, the information related to the use function may include at least one of the application of the web conference, charging availability of a conference place, necessity of use of background blurring, necessity of use of a virtual background, and necessity of use of screen sharing.

In the electronic apparatus of a fifth aspect according to the present disclosure, in any one of the first aspect to the fourth aspect, the information related to the use apparatus may include at least one of a communication environment of the conference place, screen luminance, necessity of use of a camera, necessity of use of a Bluetooth (Registered trademark, the same shall apply hereinafter) apparatus, necessity of use of a USB apparatus, and charging availability of the conference place.

In the electronic apparatus of a sixth aspect according to the present disclosure, in any one of the first aspect to the fifth aspect, the information for specifying the application used in the web conference may include a link of the web conference. Based on the link, the controller may specify the application of the web conference and based on the specified application, determine the base power consumption which is the base power consumption which is the power that can be consumed by using the application.

By using such conference information, it is possible to automatically specify an application from the link of the web conference described in a schedule or a conference guide mail. Then, the inventor has found that the power consumption of the web conference depends on the application to be used. Therefore, as compared with the related art, the electronic apparatus can more accurately calculate predicted power consumption by the web conference based on the link of the web conference.

In the electronic apparatus of a seventh aspect according to the present disclosure, in the sixth aspect, the storage may store a comparison table of information related to the use function or the use apparatus of the web conference and the optional power consumption corresponding to the use function or the use apparatus. The optional power consumption is power that can be consumed by using the use function or the use apparatus. The controller may determine the optional power consumption corresponding to the determined information related to the use function or the use apparatus based on the comparison table.

In this way, it is possible to calculate the predicted power consumption by subdividing the use function or the use apparatus of the application of the web conference that affects the power consumption. Since the influence of each of the use function or the use apparatus of the web conference to be predicted is specifically considered, the predicted power consumption consumed in the web conference can be calculated more accurately.

In the electronic apparatus of an eighth aspect according to the present disclosure, in the seventh aspect, the base power consumption can be set based on a history of actual power consumption by the application of the conference. In addition, the optional power consumption in the comparison table can be set based on the history of the actual power consumption by each of the information related to the use function or the use apparatus.

In the electronic apparatus of a ninth aspect according to the present disclosure, in the seventh aspect, the controller may determine a predicted conference time related to the time during which the web conference is held based on the acquired conference information. The controller may calculate the predicted power consumption of the web conference based on the base power consumption, the optional power consumption, and the predicted conference time.

In the electronic apparatus of a tenth aspect according to the present disclosure, in the ninth aspect, the base power consumption and the optional power consumption may be power consumption within unit time. The predicted power consumption of the web conference can be calculated by multiplying the predicted conference time by the total value of the base power consumption and the optional power consumption.

According to the estimation method in which the base power consumption by the application that greatly affects the power consumption is taken into consideration using the optional power consumption by the use function or the use apparatus, the predicted power consumption by the web conference can be calculated particularly accurately.

In the electronic apparatus of an eleventh aspect according to the present disclosure, in any one of the first aspect to tenth aspect, the controller may perform the following procedure. That is, the controller may acquire the user's schedule in which the schedule of the web conference is registered. Based on the schedule, the controller may determine whether or not the user is scheduled to go out on the day on which the schedule of the web conference is registered. In a case where it is determined that the user is scheduled to go out, the controller may determine whether or not the battery drivable time becomes insufficient based on the predicted power consumption and the remaining capacity of the battery. In a case where it is determined that the battery drivable time becomes insufficient, the controller may acquire a visiting place, movement time to the visiting place, and area information of the visiting place based on the schedule. Then, based on the area information, the movement time, and the charge time for charging the insufficient power, the controller may determine at least one movement schedule including a chargeable place and charge time. The area information may include information related to the chargeable place.

By using the predicted power consumption calculated more accurately, it is possible to more accurately determine whether or not the battery drivable time becomes insufficient. Then, in a case where the user is scheduled to go out and the battery drivable time may become insufficient, the chargeable place while the user is out and the charge time can be determined based on the area information and the like. That is, the electronic apparatus can determine the movement schedule including the chargeable place and the charge time based on the schedule of the web conference.

In the electronic apparatus of a twelfth aspect according to the present disclosure, in the eleventh aspect, in a case where it is determined that the user is scheduled to go out, the controller may perform the following procedure. That is, the controller may calculate the predicted power consumption of one or more web conferences registered on the day on which it is determined that the user is scheduled to go out. The controller may compare the remaining capacity of the battery with the predicted power consumption of one or more web conferences to determine whether or not the battery drivable time becomes insufficient. Then, in a case where it is determined that the battery drivable time becomes insufficient, the controller may perform the following procedure. That is, based on the predicted power consumption of one or more web conferences and the remaining capacity of the battery, the controller may determine the timing at which the remaining capacity of battery becomes insufficient and the charging power for charging the insufficient power. The controller may determine the charge time based on the charging power. Based on the area information, the charge time, and the timing of becoming insufficient, the controller may determine at least one movement schedule.

In the electronic apparatus of a thirteenth aspect according to the present disclosure, in the eleventh aspect or twelfth aspect, the controller may determine at least one movement schedule by optimizing the at least one movement schedule for the movement distance or the charge time for charging.

In this way, it is possible to determine the movement schedule optimized for the movement distance or the movement schedule optimized for the charge time. More appropriate movement schedules can be provided, especially when a plurality of charges is required.

In the electronic apparatus of a fourteenth aspect according to the present disclosure, in any one of the eleventh aspect to the thirteenth aspect, the electronic apparatus may further include a display. The controller may cause the display to display at least one movement schedule. The controller may cause the display to display the chargeable place and the charge time together with the schedule. Alternatively, the controller may cause the display to display the chargeable place and the charge time as a notification message.

In this way, it is possible to prompt the user to charge via the notification message. For example, when the chargeable place and charge time are displayed together with the schedule, the user can check whether the charge is required or not at the time of checking the schedule of a conference or the like, or can check a proposal or the like when the charge is required. That is, the movement schedule can be presented in an easy-to-understand manner.

In the electronic apparatus of a fifteenth aspect according to the present disclosure, in the fourteenth aspect, the controller may cause the display to display the movement schedule via a GUI indicating transition of predicted battery charging and discharging. The GUI may further indicate at least one of a title of the web conference, a conference place, a conference date and time, a chargeable place, and a charge time.

In this way, the user can confirm the transition of the predicted battery charging and discharging together with the movement schedule. Since the user can intuitively understand necessity of charging and the timing of charging by looking at the transition of battery charging and discharging, it is also possible to prompt the user to charge the battery.

In the electronic apparatus of a 16th aspect according to the present disclosure, in the 15th aspect, the electronic apparatus may further include an input unit. In a case where a plurality of movement schedules exists, the controller may receive a selection instruction to select one of the plurality of movement schedules via the input unit. Based on the selection instruction, the controller may cause the display to display the selected movement schedule.

In the electronic apparatus of a seventeenth aspect according to the present disclosure, in the 16th aspect, the controller may add, to the schedule, charging at the chargeable place for the charge time in the selected movement schedule.

In this way, the plurality of movement schedules can be proposed to the user, and the user can select a desired movement schedule. In addition, charging can be automatically added to the schedule by user's selection.

In the electronic apparatus of an eighteenth aspect according to the present disclosure, in any one of the first aspect to seventeenth aspect, the storage may store a battery driving history that records that the electronic apparatus is driven by a battery. The controller may perform the following procedure. That is, the controller may acquire the schedule of the user in which the schedule of the web conference is registered, and determine whether or not the user is scheduled to go out on the day when the web conference is registered based on the schedule. In a case where it is determined that the user is not scheduled to go out, the controller may calculate the battery driving frequency based on the battery driving history. In a case where the battery driving frequency is equal to or higher than a frequency threshold, the controller may execute a first charge control mode so that the remaining capacity of the battery is maintained within a first range.

By automatically maintaining the remaining capacity of the battery within the predetermined first range, it is possible to prevent deterioration of the battery. Since the predicted power consumption calculated more accurately is used, it is possible to more accurately determine whether to execute the first charge control mode.

In the electronic apparatus of a nineteenth aspect according to the present disclosure, in the eighteenth aspect, in a case where the battery driving frequency is less than the frequency threshold, the controller may execute a second charge control mode so that the remaining capacity of the battery is maintained within a second range. The second range is lower than the first range.

That is, in a case where the user is not scheduled to go out and the battery driving frequency is relatively low, the electronic apparatus automatically maintains the remaining capacity of the battery within the relatively low second range. In this way, it is possible to more effectively prevent deterioration of the battery.

In the electronic apparatus of a twentieth aspect according to the present disclosure, in the eighteenth aspect or nineteenth aspect, the controller may perform the following procedure. That is, in a case where it is determined that the user is scheduled to go out, the controller may calculate predicted use capacity of the battery based on the predicted power consumption and determine whether or not the predicted use capacity is equal to or more than a capacity threshold. In a case where it is determined that the predicted use capacity is equal to or more than the capacity threshold, the controller may execute a third charge control mode so that the remaining capacity of the battery is maintained within a third range. The third range is higher than the first range.

In this way, in a case where the user is scheduled to go out and the predicted use capacity is relatively high, the remaining capacity is not forcibly maintained low, so that the user can use the electronic apparatus safely even when going out. In addition, since the predicted power consumption calculated more accurately is used, it is possible to more accurately determine whether or not the remaining capacity of the battery is sufficient when going out.

In the electronic apparatus of a twenty-first aspect according to the present disclosure, in the twentieth aspect, in a case where the predicted use capacity is less than the capacity threshold, the controller may execute the first charge control mode so that the remaining capacity of the battery is maintained within the first range.

In the electronic apparatus of a twenty-second aspect according to the present disclosure, in any one of the eighteenth aspect to twentieth aspect, the controller may calculate the predicted use capacity of the battery based on the predicted power consumption. Then, the controller may calculate the predicted use capacity of the battery based on the predicted power consumption. The controller may periodically perform calibration processing of charging the battery after setting the remaining capacity of the battery to 0% based on the predicted use capacity.

In the electronic apparatus of a twenty-third aspect according to the present disclosure, in any one of the first aspect to twenty-second aspect, the controller may perform the following procedure. That is, the controller may determine whether or not the battery is connected to an external power supply. When determining that the battery is connected to the external power supply, the controller may determine whether or not the power of the external power supply is less than the rated power of the electronic apparatus. When determining that the power of the external power supply is less than the rated power of the electronic apparatus, the controller may acquire a priority mode setting. Based on the priority mode setting, the controller may select and execute a performance priority mode in which power is preferentially supplied to a central processing unit (CPU) so that the performance of the CPU of the electronic apparatus is not degraded or a charge priority mode in which power is preferentially supplied to the battery.

In this way, for example, in a case where the user uses an adapter that is less than the rated power when going out, the performance priority mode or the charge priority mode can be appropriately selected and executed. In particular, since the predicted power consumption calculated more accurately in each mode is used, the power supply control can be executed more accurately.

In the electronic apparatus of a twenty-fourth aspect according to the present disclosure, in the twenty-third aspect, when determining that the power supplied to the CPU is less than the first power threshold in the performance priority mode, the controller may change a power supply option of an operating system (OS) of the electronic apparatus, stop power supply to an input unit or a connection port of the electronic apparatus, stop power supply to a component whose power consumption is equal to or greater than the second power threshold in the electronic apparatus, or stop power supply to the battery, so as to reduce the power consumption of the electronic apparatus.

In the electronic apparatus of a twenty-fifth aspect according to the present disclosure, in the twenty-third aspect, when determining that the power supplied to the battery is less than the third power threshold in the charge priority mode, the controller may change a power supply option of the OS of the electronic apparatus, stop power supply to the input unit or the connection port of the electronic apparatus, stop power supply to a component whose power consumption is equal to or greater than the second power threshold in the electronic apparatus, or limit power to the CPU, so as to reduce power consumption of the electronic apparatus.

Since the power consumption of the electronic apparatus can be predicted more accurately, the power supply control can be executed more accurately even in the performance priority mode or the charge priority mode. In particular, it is possible to more accurately determine whether to change the power supply option of the OS of the electronic apparatus.

A control method for controlling the electronic apparatus including the battery of the twenty-sixth aspect according to the present disclosure, the control method includes steps of: acquiring conference information related to a web conference, in which the conference information includes information for specifying an application used in the web conference, a conference date and time of the web conference, and information related to a conference place or a conference participant; and determining information related to a use function or a use apparatus used in the application of the web conference based on the acquired conference information; calculating predicted power consumption consumed in the web conference based on the determined information related to the use function or the use apparatus; and calculating a change in remaining capacity of the battery based on the calculated predicted power consumption and the remaining capacity of the battery.

A computer program of a twenty-seventh aspect according to the present disclosure is a computer program for causing the electronic apparatus to execute the control method of the twenty-sixth aspect.

A storage medium of a twenty-eighth aspect according to the present disclosure is a non-transitory computer-readable storage medium storing a computer program. The control method of the twenty-sixth aspect is implemented when the computer program is executed by a processor.

According to the control method, the computer program, or the recording medium as in the twenty-sixth aspect to twenty-eighth aspect, the method or the like can analyze the conference information to automatically determine the information related to the use function or the use apparatus used in the application of the web conference. By considering use conditions of the application of the web conference such as the use function or the use apparatus, predicted power consumption consumed in the web conference can be calculated more accurately. As a result, the overall power consumption of the electronic apparatus can be predicted more accurately, and the application using the prediction result of the power consumption can be more appropriately performed.

«Technical concept»

Prior to describing specific exemplary embodiments of the electronic apparatus, the control method, the computer program, and the storage medium according to the present disclosure, first, a technical concept described in the present disclosure will be described with reference to an example. In an example of the present disclosure, a user of an electronic apparatus is scheduled to host or participate in a web conference using the electronic apparatus. The electronic apparatus includes the controller, the storage, and the battery, and can predict a change in power consumption and the remaining capacity of the battery by the web conference. Then, using the prediction result, the electronic apparatus can perform further application, for example, charge control, proposal of a chargeable place and charge time, battery degradation prevention control, power supply control to a component of the electronic apparatus, and the like.

In order to predict the power consumption by the web conference, the controller acquires the conference information related to the web conference such as a conference date and time and a conference place. The controller determines information related to a use function or a use apparatus used in the application of the web conference based on the acquired conference information. For example, in the web conference, it is determined to use the camera and background blurring function. Then, in this example, the controller calculates predicted power consumption consumed in the web conference based on base power consumption by the application of the web conference and optional power consumption by the determined information related to the use function or the use apparatus. That is, the controller calculates a result obtained by adding the optional power consumption to the base power consumption as the predicted power consumption. Then, the controller calculates a change in the remaining capacity of the battery based on the calculated predicted power consumption and the remaining capacity of the battery.

Note that, in the present disclosure, a method for predicting power consumption by the web conference will be described in detail, but power consumption by other applications of the electronic apparatus can be predicted as before.

Each of the exemplary embodiments described below illustrates an example of the present disclosure. Numerical values, shapes, configurations, steps, and orders of the steps, and the like illustrated in each of the following exemplary embodiments are merely examples, and thus are not intended to limit the present disclosure. Among the constituent elements in the following first exemplary embodiment, constituent elements not recited in the independent claim indicating the highest concept are described as optional constituent elements.

In each of the exemplary embodiments to be described below, modifications may be illustrated for specific elements, and an appropriate combination of any configurations is included for other elements, and each effect is achieved in the combined configuration. In the exemplary embodiments, the configurations of the modifications are combined, whereby the effects of the modifications are obtained.

In the following detailed description, the terms “first”, “second”, and the like are only used for description, and should not be understood as explicitly or implying relative importance or a rank of a technical feature. Features limited to “first” and “second” are intended to explicitly or implicitly indicate the inclusion of one or more such features.

### First Exemplary Embodiment

Hereinafter, a first exemplary embodiment of an electronic apparatus, a control method, a computer program, and a storage medium according to the present disclosure will be described in detail with reference to the drawings as appropriate.

### <Overall Configuration>

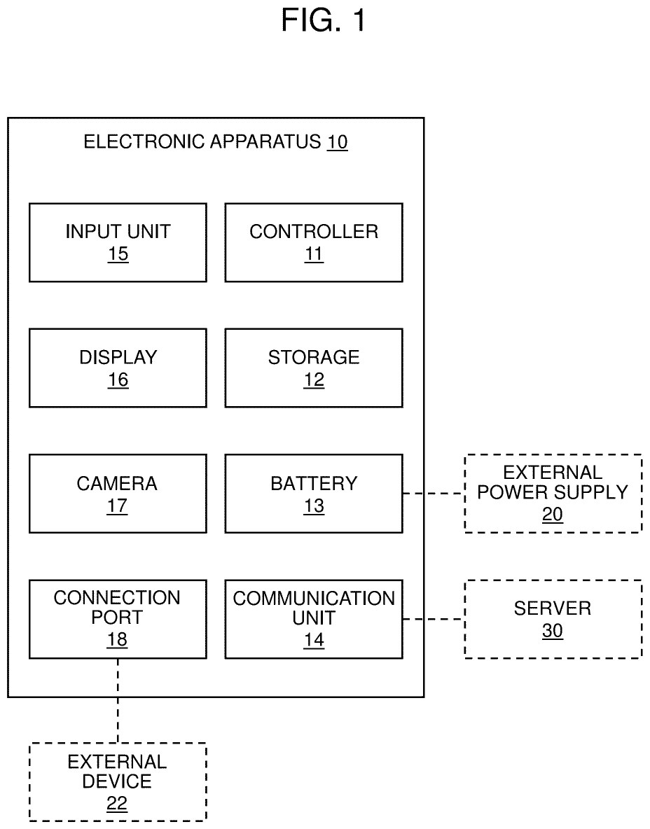

FIG. 1 is an example of a block diagram illustrating a configuration of electronic apparatus 10 according to a first exemplary embodiment.

### <Electronic Apparatus 10>

As illustrated in FIG. 1, electronic apparatus 10 includes controller 11, storage 12, and battery 13. Electronic apparatus 10 may be a laptop computer including a notebook computer, a tablet terminal, a smartphone, or the like. Battery 13 supplies power to controller 11 and storage 12. As described later, electronic apparatus 10 may appropriately include other components such as communication unit 14, input unit 15, display 16, camera 17, and connection port 18 according to the application. Battery 13 supplies power to at least a part of the components of electronic apparatus 10.

### <Controller 11>

Controller 11 is a controller that controls entire electronic apparatus 10. Controller 11 includes a general-purpose processor such as a CPU or an MPU that implements a predetermined function by executing a program stored in storage 12. Controller 11 implements various controls in electronic apparatus 10 by calling and executing a control program based on a control method. Controller 11 is not limited to one that implements the predetermined function through cooperation of hardware and software, but the controller 11 may be a hardware circuit designed exclusively for implementing the predetermined function. In other words, controller 11 can be achieved by various processors such as a CPU, an MPU, a GPU, an FPGA, a DSP, and an ASIC.

### <Storage 12>

Storage 12 is a recording medium that records various pieces of information and control programs, and may be a memory that functions as a work area of controller 11. Storage 12 is implemented by, for example, a flash memory, a RAM, a solid state device (SSD), a hard disk, other storage devices, or an appropriate combination thereof. Storage 12 stores an instruction executed by controller 11. The computer program for causing the electronic apparatus to execute the control method for controlling electronic apparatus 10 may include an instruction executed by controller 11.

### <Battery 13>

Battery 13 may be a built-in battery or a removable battery, and can supply power to at least some of the components of electronic apparatus 10 when there is still a remaining capacity of possessed power. In case of being connected to external power supply 20, battery 13 supplies power for the operation of electronic apparatus 10 using external power supply 20 as a driving power supply. Controller 11 can perform control related to various charging and discharging to be described later on battery 13.

### <Communication Unit 14>

Communication unit 14 can be connected to the Internet, and can communicate with arbitrary server 30 by transmitting and receiving internet packets via the Internet. Controller 11 may cooperate with server 30 and/or another electronic apparatus via communication unit 14. Communication unit 14 can communicate through a LAN, a WLAN, or a WWAN. For example, communication unit 14 may perform communication in accordance with a standard such as Wi-Fi (registered trademark), IEEE 802.2, IEEE 802.3, 3G, or LTE to transmit and receive data. In addition to the Internet, communication unit 14 may perform communication through infrared rays or Bluetooth such as an intranet, an extra net, ISDN, VAN, a CATV communication network, a virtual dedicated network, a telephone line network, a mobile communication network, or a satellite communication network. The communication unit may include, for example, a circuit capable of communicating in accordance with the above-described standard.

### <Input Unit 15>

Input unit 15 is an input interface that receives an instruction from a user. Input unit 15 may include, for example, a mouse, a keyboard, a touch panel, a touch pad, a switch, a button, a microphone, and the like. Input unit 15 converts a content of an instruction or an operation received from the user into an electric signal and transmits the electric signal to controller 11.

### <Display 16>

Display 16 is a device capable of displaying a user's schedule, information related to battery 13, and a GUI related to an application such as a web conference application. The screen luminance of display 16 can be automatically changed under the control of controller 11, or can be changed according to a user's instruction. The higher the screen luminance, the brighter the screen appears, and the higher the power consumption by display 16.

### <Camera 17>

Camera 17 may be various cameras such as a camera built in a notebook computer, an external camera, a camera equipped with a wide-angle lens, and a camera having an automatic tracking function of automatically tracking a user who is speaking. In a case where electronic apparatus 10 includes camera 17, camera 17 can be used for a web conference to capture a shadow image of the user for presentation to the participants of the web conference.

### <Connection Port 18>

Electronic apparatus 10 can be connected to various external devices 22 via connection port 18. Connection port 18 may be, for example, a USB port, a COM port, an HDMI (registered trademark) port, a DVI, a display port (DisplayPort), or a VGA. Electronic apparatus 10 can be connected to a Bluetooth apparatus via a USB port or a COM port. Electronic apparatus 10 can be connected to an external device 22 such as an input device, a display, an audio apparatus, a storage, or a camera, which is located outside, via connection port 18. For example, connection port 18 includes a USB Type C port, and electronic apparatus 10 can be connected to external device 22 called an external monitor via a USB power delivery (PD) connection using connection port 18. Electronic apparatus 10 can supply power to an external monitor and/or can be supplied from the external monitor via connection port 18, which is a USB Type C port, and a USB PD connection. In addition, via connection port 18, which is a USB port, electronic apparatus 10 can supply power to external device 22 such as a smartphone, a mouse, a keyboard, and a communication apparatus (a Wi-Fi router or the like) connected thereto via the USB port.

### <External Power Supply 20>

Battery 13 can be connected to external power supply 20 via, for example, an AC adapter. When connected to external power supply 20, Battery 13 can be repeatedly charged. In a case where battery 13 is connected to external power supply 20, the sum of power supplied from external power supply 20 to electronic apparatus 10 and power charged from external power supply 20 to battery 13 is constant. That is, external power supply 20 supplies power for charging battery 13 with reserve power of power supplied as power consumption of electronic apparatus 10. Therefore, when the power consumption is reduced, the charging power of battery 13 increases. Increasing the charging power of battery 13 means increasing a current for charging battery 13. For example, increasing a current provided via the AC adapter enables increase of charging power of battery 13 and shortening of charge time of battery 13. Shortening the charge time of battery 13 enables extension of available driving time of battery 13.

### <Server 30>

Server 30 can be connected to electronic apparatus 10 via the Internet. For example, server 30 may be a server for a manufacturer of electronic apparatus 10 to manage electronic apparatus 10. In addition, server 30 may be a server managed by an application service provider (ASP) that provides web conference services or system integration (SI). Server 30 may be a server that provides a service related to an online schedule. Server 30 may be a server that provides a service related to electronic mail. Server 30 may execute a control method to be described later in cooperation with electronic apparatus 10, and may store data such as information and a database used for the control method. Controller 11 of electronic apparatus 10 can acquire data stored in server 30 via communication unit 14 and the Internet.

### <Control Method for Controlling Electronic Apparatus 10>

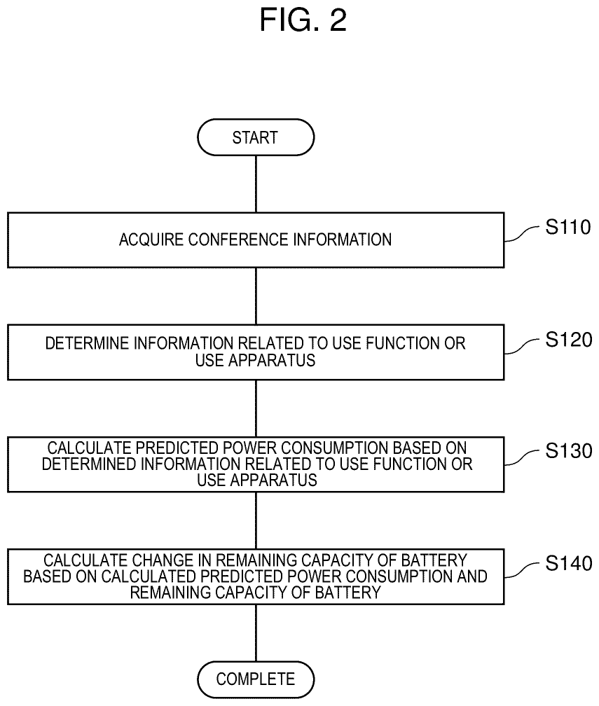

Controller 11 described above can execute a control method for controlling electronic apparatus 10. This control method is suitable in a case where the user of electronic apparatus 10 is scheduled to hold a web conference using electronic apparatus 10. For example, electronic apparatus 10 may read a user's schedule or a web conference guide mail to acquire information indicating a schedule of the web conference and recognize the schedule of the web conference. Then, electronic apparatus 10 may predict a change in power consumption and the remaining capacity of battery 13 by the web conference using this control method. FIG. 2 is a flowchart of an example of a control method in the first exemplary embodiment.

First, controller 11 acquires conference information related to the web conference to be held (step S110). Controller 11 may acquire at least a part of the conference information from a user's schedule in which the schedule of the web conference is registered, from a web conference guide mail, or from a user input. For example, controller 11 acquires the user's schedule by reading the schedule from storage 12 or downloading the schedule from the Internet.

An example of the schedule includes “.ics” file (file of “iCalender”) created by a calendar function of Google (registered trademark) or Outlook (registered trademark), but is not limited thereto. In one example, controller 11 acquires information related to the schedule from the web conference guide mail or the user input, and creates the user's schedule. Even in a case where the schedule can be directly acquired from the Internet or the like, controller 11 can create another schedule based on the acquired web conference guide mail or the like. In addition, controller 11 may integrate the schedule acquired from the Internet or the like and the schedule created by controller 11, and perform the control method of the present disclosure using the integrated schedule.

At least two of applications of the web conference, the schedule, and the email can be interlocked. For example, according to Outlook (registered trademark), the schedule of the web conference can be automatically registered in a schedule of the Outlook (registered trademark) based on a guide mail for the web conference using Teams (registered trademark) of Microsoft (registered trademark). In a case where the content of the guide mail is included in the schedule in this manner, controller 11 can acquire the conference information described in the guide mail even if the schedule is read instead of the guide mail.

Based on the acquired schedule, controller 11 determines whether or not the conference information for performing the control method is sufficient. If it is determined that the conference information is not sufficient, the controller may prompt the user to input an insufficient portion. In one example, if it is determined that the conference information is not sufficient, controller 11 may acquire a schedule of a person other than the user or an organization or a web conference guide mail via server 30. For example, controller 11 can acquire a schedule of other participants of the web conference via server 30 and acquire additional conference information from the schedule of other participants.

Subsequently, controller 11 determines information related to a use function or a use apparatus used in the application of the web conference based on the acquired conference information (step S120). As will be described in detail later, based on various conference information, it may be determined which function of the application, or which component in electronic apparatus 10, or which external device 22 may be used in the web conference. In particular, controller 11 can determine information related to a use function or a use apparatus that may affect power consumption. For example, controller 11 may determine the application used for the web conference from the link of the web conference, or may determine whether or not camera 17 or the background blurring function is used in the web conference.

Controller 11 calculates predicted power consumption consumed in the web conference based on the information related to the use function or the use apparatus determined in step S120 (step S130). For example, in a case where it is determined that camera 17 and the background blurring function are used in the web conference, the predicted power consumption can be calculated based on the power consumption by the application to be used, camera 17, and the background blurring function.

Subsequently, based on the predicted power consumption calculated in step S130 and the remaining capacity of battery 13, controller 11 calculates a change in the remaining capacity of battery 13 (step S140). In short, the remaining capacity after the change (after the web conference) can be calculated by subtracting the predicted power consumption from the original remaining capacity of battery 13. Note that, in a case where the predicted power consumption is larger than the remaining capacity of battery 13, controller 11 may determine a change that the remaining capacity of battery 13 does not become negative but the remaining capacity becomes insufficient.

Hereinafter, what kind of conference information can be acquired, and how information related to the use function or the use apparatus is determined based on the conference information will be described. In addition, the use function and the use apparatus may be collectively referred to as “use conditions”.

### <Conference Information>

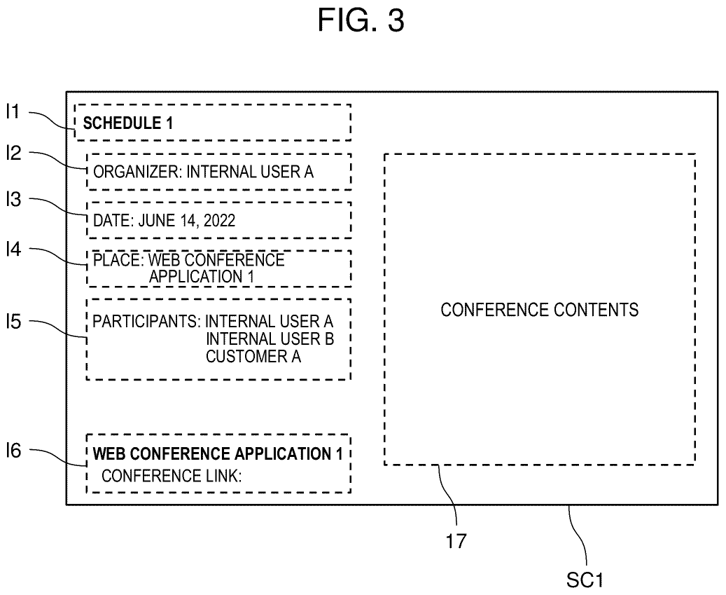

FIG. 3 is an example of conference information in the first exemplary embodiment. The GUI of the web conference guide mail is displayed on screen SCI illustrated in FIG. 3. The GUI includes various items, and may include, for example, a conference title item I1, a conference organizer item I2, a conference date and time item I3, a conference place item I4, a conference participant item I5, item I6 of an information for specifying an application used in a web conference, and a conference content item I7. In addition, the conference title item I1 or the conference content item I7 may include information related to the conference type.

For example, the conference type can be determined based on the conference title item I1 or the conference content item I7. The conference type may be, for example, a regular conference (months, weeks, etc.), a 1-on-1 conference, viewing of a seminar, holding of a seminar, or a workshop. Based on the conference organizer item I2, it is possible to determine whether or not the user of electronic apparatus 10 is an organizer of the web conference. Based on the conference date and time item I3, it is possible to determine whether the conference is held during the day or night and the conference time (the length of time of the conference). Based on the conference place item I4, it is possible to determine the place where the user performs the web conference, for example, the home, the office desk, the visiting place, or a conference room of another company. Based on the conference participant item I5, it is possible to determine whether or not the other party of the web conference includes an external person. Based on item I6 of information for specifying an application to be used in the web conference, it is possible to determine which application is to be used in the web conference.

In one example, the information for specifying the application to be used in the web conference is a link of the web conference. The link of the web conference may be a URL or IP address that can access to a particular web conference. For example, in a case where the link of the web conference has a format starting with “https://teams.live.com”, controller 11 can determine that the application to be used in the web conference is “Teams”. In addition, for example, in a case where the link of the web conference includes “zoom.us”, controller 11 can determine that the application to be used in the web conference is “Zoom”.

In another example, the information for specifying the application to be used in the web conference includes a name, an abbreviation, a code, an icon, and the like of the application. Examples of the application to be used in the web conference include Zoom (registered trademark), Teams (registered trademark) of Microsoft (registered trademark), and Meet (registered trademark) of Google (registered trademark), but are not limited thereto. The list of applications available in the web conference can be stored in storage 12 and/or server 30 of electronic apparatus 10 and can be updated at any time. In one example, server 30 maintains the list of available applications. Based on the input of the user of electronic apparatus 10, the input of the administrator of server 30, or the automatically acquired information, server 30 may add, to the list, information for specifying a new application that can be used in electronic apparatus 10 and whose power consumption can be predicted.

### <Use Function or Use Apparatus>

In step S120, controller 11 determines information related to a use function or a use apparatus used in the application of the web conference based on the acquired conference information. That is, controller 11 determines what use conditions the web conference is held under. The criterion for determination may be determined in advance, or may be based on a history of these use conditions in the past web conferences or statistical data thereof.

The information related to the use function may include, for example, at least one of a web conference application, charging availability of a conference place, necessity of use of background blurring, necessity of use of a virtual background, and necessity of use of screen sharing.

The information related to the use apparatus may include, for example, at least one of a communication environment of the conference place, screen luminance of display 16, necessity of use of camera 17, necessity of use of the Bluetooth apparatus via connection port 18, necessity of use of the USB apparatus via connection port 18, and charging availability of the conference place. Note that, the information related to the use apparatus may include necessity of use of external device 22 connected via a connection port in a format other than Bluetooth or a USB port or a connection method.

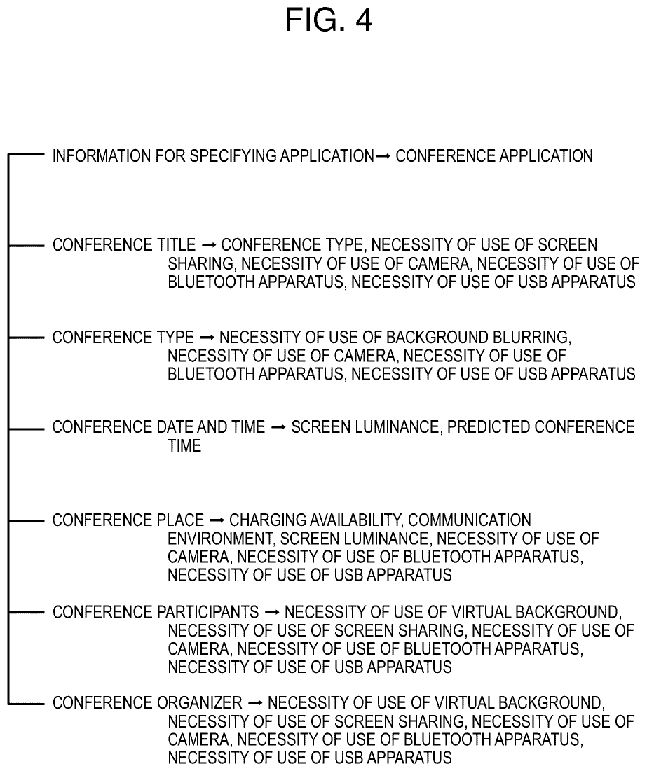

FIG. 4 is an example of the use conditions in the first exemplary embodiment. FIG. 4 illustrates an example indicating which use conditions can be determined from specific conference information.

First, controller 11 can specify the application based on information for specifying the application to be used in the web conference, for example, a link, a name, an abbreviation, a code, an icon, or the like of the web conference. That is, it is possible to determine which application is used to perform the web conference.

Controller 11 may determine the conference type or the conference content based on the conference title. Then, it is possible to determine necessity of use of background blurring, necessity of use of camera 17, necessity of use of the Bluetooth apparatus, necessity of use of the USB apparatus, and the like based on the conference type or the conference content. For example, from a conference title such as “division conference in August”, it can be seen that the web conference is a regular internal conference. Since the regular conference is a conference whose content has high redundancy due to its nature, it is possible to predict an action that the user can perform in the regular conference based on a history of previous similar regular conferences. Therefore, based on the history of the past regular conference, controller 11 may determine necessity of use of the screen sharing, necessity of use of camera 17, necessity of use of the Bluetooth apparatus, and necessity of use of the USB apparatus during the web conference.

As another example, assuming that it can be seen that the conference type is viewing of all hands meeting (AHM) or seminar. In Japan, when the AHM is performed or a seminar is viewed, in a case where the user is not the organizer, controller 11 may determine that use of own screen sharing and camera 17 are not necessary. As another example, assuming that in a case where it is determined that the conference type is a discussion conference or a 1on1 conference, there is a high possibility that camera 17 needs to be used. Furthermore, assuming that in a case where the participants of the discussion conference are only in-house personnel, there is a high possibility that the background blurring or virtual background function does not need to be used. On the other hand, in a case where external personnel also participates in the discussion conference, it is relatively likely that the background blurring or virtual background function is used from the viewpoint of confidentiality.

Then, controller 11 can determine the screen luminance of display 16 of electronic apparatus 10 based on the conference date and time and/or the conference place. In general, in order to make the screen more visible, the brighter the place where electronic apparatus 10 is located, the higher the screen luminance should be set. That is, the brighter the conference place, the higher the screen luminance is set, and the higher the power consumption tends to be. Therefore, in a case where the conference place is in a room such as a home, an office desk, or a conference room, controller 11 may determine that the environment is relatively bright and the screen luminance is set to be relatively high. On the other hand, in a case where the conference place is outdoors and the conference date and time is nighttime, it may be determined that the environment is relatively dark and the screen luminance is set relatively low. In addition, in a case where the conference place is outdoors, there is a high possibility that there is a relatively large amount of noise, and thus, controller 11 may determine that it is necessary to use the Bluetooth apparatus such as an carphone.

Based on the conference date and time, the conference type, or the conference content, controller 11 can predict the time (predicted conference time) when the web conference is actually held. For example, in a case where the web conference is a regular conference, based on the history of the past regular conference, it is possible to know whether the regular conference ends on time, how long the regular conference extends, or how early the regular conference ends. Therefore, controller 11 can further determine the predicted conference time based on the history. In addition, for example, in a case where the web conference is a viewing of an external seminar, there is a high possibility that the conference ends on time, and thus, controller 11 may determine the predicted conference time according to the scheduled conference date and time.

Controller 11 may further determine, based on the conference place, charging availability in the conference place, a communication environment, necessity of use of camera 17, necessity of use of Bluetooth apparatus, necessity of use of the USB apparatus, and the like. For example, in a case where the conference place is the user's desk, controller 11 may determine that charging is possible, communication is performed through LAN, and use of camera 17 is unnecessary. In addition, assuming that in a case where the conference place is a conference room of another company, controller 11 may determine that charging is impossible and communication is performed through WLAN. In one example, controller 11 can determine necessity of use of the USB apparatus such as an external monitor or a Wi-Fi router based on the conference place. In case of determining that the USB apparatus needs to be used, controller 11 may further determine the type of the USB apparatus (for example, a display, an input device, or a communication device).

Note that, the communication environment refers to a type of communication performed by the communication unit 14, that is, a communication connection method. For example, the information related to the use apparatus called the communication environment may include “communication through wired LAN”, “communication through wireless LAN (WLAN)”, and “communication through WWAN”.

Based on the conference participants, controller 11 may further determine necessity of use of the virtual background, necessity of use of the screen sharing, necessity of use of camera 17, necessity of use of use the Bluetooth apparatus, necessity of use of the USB apparatus, or the like. For example, in a case where the conference participants are only in-house personnel, controller 11 may determine that the function of the background blurring or the virtual background does not need to be used, the screen sharing needs to be used, and camera 17 does not need to be used. On the other hand, in a case where the conference participants include a person belonging to an organization different from the user, controller 11 may determine that the function of the background blurring or the virtual background needs to be used.

In addition, based on the conference organizer, for example, based on whether or not the user is the conference organizer, controller 11 may further determine necessity of use of the background blurring, necessity of use of the virtual background, necessity of use of the screen sharing, necessity of use of the camera, necessity of use of the Bluetooth apparatus, necessity of use of the USB apparatus, or the like. For example, in a case where the user is a conference organizer, controller 11 may determine that background blurring does not need to be used, the screen sharing needs to be used, the camera needs to be used, the Bluetooth apparatus of an carphone or a microphone needs to be used, and the USB apparatus of an external monitor needs to be used. On the other hand, in a case where the user is not the conference organizer, controller 11 may determine that the screen sharing does not need to be used, the camera does not need to be used, the Bluetooth apparatus of an earphone needs to be used, and the USB apparatus does not need to be used.

Hereinafter, how to calculate predicted power consumption based on information related to the application, the use function, or the use apparatus used for the web conference will be described.

### <Calculation of Predicted Power Consumption of Web Conference>

As described above, controller 11 determines an item that may affect power consumed by holding the web conference, that is, the application of the web conference, and the use function or the use apparatus used in the web conference. Then, controller 11 determines the power consumed by each of these items and adds up the power to obtain predicted power consumption.

First, the inventor has found that the power consumption of the web conference depends on the application used. That is, the power consumption by the application of the web conference is one of factors having a large influence on the predicted power consumption. Therefore, controller 11 may specify an application to be used in the web conference and determine the base power consumption corresponding to the application. The base power consumption refers to power that can be consumed by use of the application.

The conference information includes information for specifying an application to be used in the web conference. In one example, the information for specifying the application to be used in the web conference includes the link of the web conference. As described above, controller 11 can specify the application of the web conference based on the link of the web conference. In step S130, controller 11 determines the base power consumption based on the specified application. In one example, storage 12 stores a comparison table of each application and the corresponding base power consumption. In step S130, controller 11 acquires the base power consumption by collating the comparison table with the specified application.

In one example, the base power consumption is power consumption within the unit time. For example, when using a corresponding application, power consumption may be per minute, per 5 minutes, per 10 minutes, per 30 minutes, per 60 minutes. The base power consumption may be set based on a history of actual power consumption by the application. For example, for each web conference, a history of used applications and actual measured power consumption (that is, an actual measurement value of power consumption) may be stored in database. The database of the history may be stored in storage 12 of electronic apparatus 10, may be stored in server 30, or may be stored in both storage 12 and server 30. The base power consumption may be set based on an average value, a median value, or a most frequent value of actual measured values of power consumption related to the application.

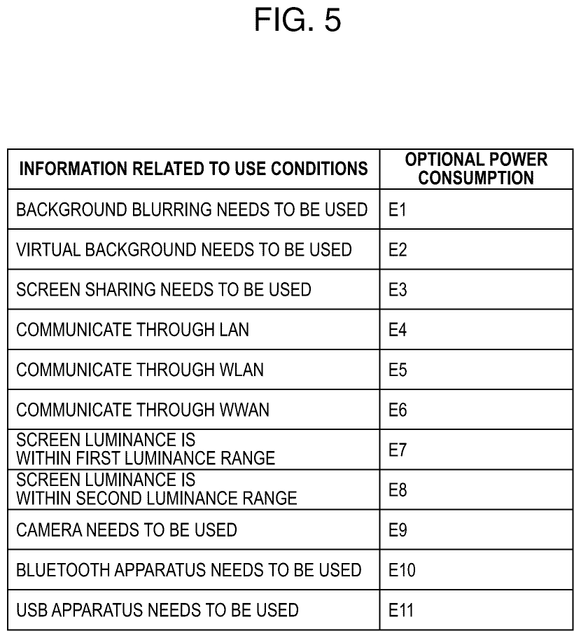

Next, storage 12 stores a comparison table of information related to the use function or the use apparatus of the web conference (hereinafter, it may be abbreviated as “use conditions”) and the optional power consumption corresponding to each of the use conditions. FIG. 5 is an example of the comparison table in the first exemplary embodiment. For example, the information related to the use function of “background blurring needs to be used” corresponds to the optional power consumption of “E1”. In the following description, the optional power consumption may be simplified to correspond to the specific use conditions.

Specifically, the optional power consumption refers to power consumption by a specific use function or use apparatus. As with the base power consumption, the optional power consumption may be power consumption within unit time. For example, when using corresponding use conditions, power consumption may be per minute, per 5 minutes, per 10 minutes, per 30 minutes, per 60 minutes.

The optional power consumption in the comparison table can be set based on the history of the actual power consumption by each of the information related to the use function or the use apparatus. For example, the optional power consumption “E1” illustrated in FIG. 5 may be set as the power consumed per minute by the use of background blurring when the use function of background blurring is used in the web conference. In one example, electronic apparatus 10 determines whether or not the respective use conditions are matched (for example, whether background blurring has been used or not) for each web conference, and stores a history of actual measurement values of power consumption under the matched use conditions in the database. The history database and the comparison table may be stored in storage 12 of electronic apparatus 10, may be stored in server 30, or may be stored in both storage 12 and server 30. In step S130, controller 11 acquires the optional power consumption by collating the comparison table under the determined use conditions.

In addition, based on the conference date and time, the conference type, the conference content, or the history of the web conference, controller 11 determines (predicts) a predicted conference time when the web conference to be predicted is actually held. For example, assuming that although the conference time is scheduled to be 1 hour according to the conference date and time of the web conference which is a regular conference, it has been found that the conference time actually increases by about 10 minutes according to the history of the past regular conference. In this case, controller 11 may determine that the predicted conference time is 70 minutes based on the history.

After determining the base power consumption, the optional power consumption, and the predicted conference time in step S130, controller 11 calculates the predicted power consumption of the web conference based on the determined base power consumption, optional power consumption, and predicted conference time. That is, controller 11 calculates a result obtained by adding the optional power consumption to the base power consumption as the predicted power consumption.

In one example, controller 11 calculates the predicted power consumption of the web conference by multiplying the predicted conference time by the total value of the base power consumption and the optional power consumption. Note that, the total value refers to the total value of the base power consumption and all the determined optional power consumption. In this example, controller 11 sets a calculation result obtained by multiplying the total value by the predicted conference time as predicted power consumption. For example, assuming that, for a web conference to be predicted, the determined use conditions are “camera needs to be used”, “virtual background needs to be used”, “communication through WLAN”, and “screen luminance is within the first luminance range”. Then, assuming that the base power consumption of the application to be used is “BE1”. In this example, controller 11 determines that the optional power consumption is E2, E5, E7, and E9 by collating the comparison table illustrated in FIG. 5. Then, controller 11 calculates a calculation result obtained by multiplying the total value of BE1, E2, E5, E7, and E9 by the predicted conference time as the predicted power consumption.

In another example, controller 11 weights specific optional power consumption and calculates the predicted power consumption based on the weighted sum of the base power consumption and the optional power consumption and the predicted conference time. For example, assuming that it is considered that the power consumption increases when a plurality of specific functions or apparatuses is used in combination. When it is determined that the plurality of functions or apparatuses is used in combination in one web conference, controller 11 may give one or more weights to the optional power consumption corresponding to at least one of the functions and the apparatuses.

As described above, controller 11 can determine the use conditions from the conference information of the web conference and calculate the predicted power consumption of the web conference based on the use conditions. Then, controller 11 can calculate the change in the remaining capacity by subtracting the predicted power consumption from the original remaining capacity of battery 13. Thereafter, controller 11 can further determine change in the drivable time of electronic apparatus 10 from the change in the remaining capacity of battery 13. For example, in a case where electronic apparatus 10 can be driven for 1 hour with a remaining capacity of 10% on average, if the remaining capacity is calculated to change from 50% to 20%, the drivable time can also be calculated to be from 5 hours to 2 hours.

As a result, the processing of calculating the predicted power consumption by the web conference and the change in the remaining capacity of battery 13 of electronic apparatus 10 is completed. Since the predicted power consumption is calculated based on the application and the use conditions affecting the power consumption, the predicted power consumption can be calculated more accurately. That is, by subdividing the use conditions, the influence of each use condition is specifically considered, so that the predicted power consumption may be calculated more accurately.

The present disclosure also provides a computer program and a storage medium for controlling electronic apparatus 10.

In one example, a computer program used to cause electronic apparatus 10 to execute the control method described above is provided.

In one example, the computer program described above is stored in a non-transitory computer-readable storage medium. When the computer program is read and executed by controller 11 of electronic apparatus 10, the above-described control method is implemented.

According to the configuration of electronic apparatus 10, the control method, the computer program, and the recording medium, it is possible to analyze the conference information and automatically determine the use conditions that can be used for the web conference. By considering the application and use conditions of the web conference, the predicted power consumption consumed in the web conference can be calculated more accurately. As a result, the overall power consumption of the electronic apparatus can be predicted more accurately, and the application using the prediction result of the power consumption can be more appropriately performed.

Electronic apparatus 10 can calculate predicted power consumption by the web conference and a change in the remaining capacity of battery 13 of electronic apparatus 10 by the above-described processing. Then, further application, for example, charge control, proposal of a chargeable place and charge time, deterioration prevention control of battery 13, power supply control to components of the electronic apparatus, and the like can be performed using the calculation result. In the following second exemplary embodiment to fifth exemplary embodiment, various applications using predicted power consumption will be described.

### Second Exemplary Embodiment

### <Determination of Movement Schedule Related to Charging>

In a second exemplary embodiment, controller 11 can determine whether or not it is necessary to perform charging within a certain period, for example, based on a schedule in one day, and determine a chargeable place and a charge time as necessary. Since the determination is made using the predicted power consumption calculated more accurately, it is possible to more accurately determine whether or not the drivable time of battery 13 becomes insufficient, when the drivable time is likely to become insufficient, and how much the remaining capacity is insufficient.

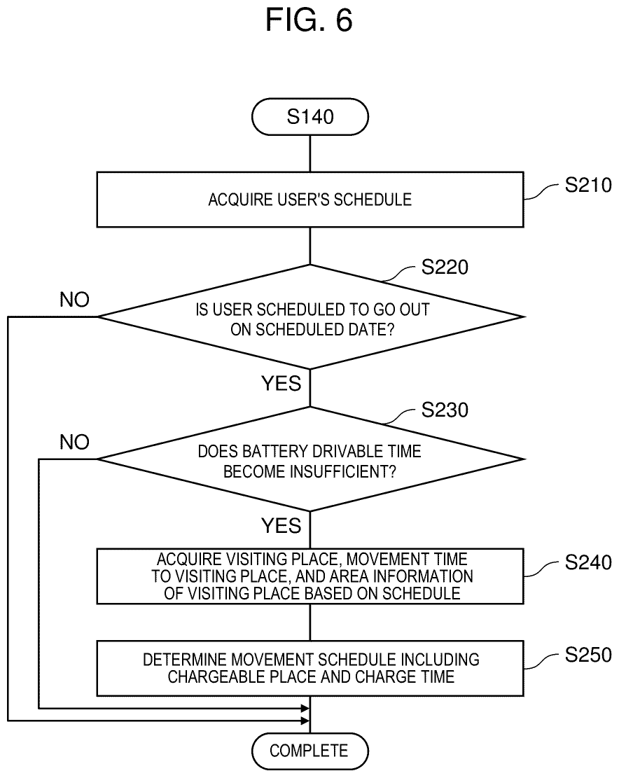

FIG. 6 is a flowchart of an example of a control method in the second exemplary embodiment. The processing described in the second exemplary embodiment may be performed after step S140 in FIG. 2 because the predicted power consumption of the web conference and the change in the remaining capacity of battery 13 calculated in the first exemplary embodiment are used.

Hereinafter, controller 11 confirms the schedule of one day of the user by exemplifying a period of one day, determines whether or not charging should be performed in the one day, and determines (creates) a movement schedule of the one day. However, controller 11 may determine the movement schedule for different periods, for example, half a day, two days, three days, and one week.

Controller 11 acquires a schedule of the user in which the schedule of the web conference is registered (step S210). For example, controller 11 can acquire the schedule of the user from storage 12 or server 30. Here, it is not necessary to acquire the entire contents of the schedule, and the contents of the schedule may be acquired for a period to be processed, for example, the date when the schedule of the web conference is registered. In addition, in a case where the schedule has already been acquired in steps S110 to S140 of FIG. 2, this step S210 can be omitted.

Based on the acquired schedule, controller 11 determines whether or not the user is scheduled to go out for the day (hereinafter, it may be abbreviated as “scheduled date”) on which the schedule of the web conference for which the predicted power consumption is calculated is registered (step S220). To go out means that the user goes to a place other than the home or an affiliation where the user usually goes (for example, the user's company, school, circle, or the like). Controller 11 may determine whether or not it is necessary to go out based on a place registered in each schedule in the schedule. For example, when a conference is scheduled to be held at another company or an outdoor conference is scheduled to be held, controller 11 may determine that there is a schedule of going out on the scheduled day.

In a case where the user is not scheduled to go out, even if the web conference is held by electronic apparatus 10 or electronic apparatus 10 is used for other purposes, it is possible to perform the conference while being connected to external power supply 20, and thus, it is not necessary to determine the timing of charging and the movement schedule. On the other hand, in a case where the user is scheduled to go out, attention should be paid to a change in the remaining capacity of battery 13 and a change in the drivable time of electronic apparatus 10. This is because, when the remaining capacity of battery 13 becomes insufficient while the user is out, a schedule for using electronic apparatus 10 thereafter is disturbed.

In a case where it is determined that the user is scheduled to go out (YES in step S220), controller 11 determines whether or not the drivable time of battery 13 becomes insufficient based on the predicted power consumption and the remaining capacity of battery 13 (step S230). Specifically, in a case where it is determined that the user is scheduled to go out, controller 11 calculates predicted power consumption of one or more web conferences registered on the scheduled date. For example, in a case where three web conferences are scheduled on the scheduled day, controller 11 may calculate predicted power consumption of each of the three web conferences based on the control method described in the first exemplary embodiment. Then, controller 11 determines a change in the remaining capacity of battery 13 based on these pieces of predicted power consumption.

Controller 11 compares the remaining capacity of battery 13 with the predicted power consumption of the one or more web conferences described above to determine whether or not the drivable time of battery 13 becomes insufficient. Then, in case of determining that the drivable time of battery 13 becomes insufficient, controller 11 determines the timing at which the remaining capacity of battery 13 becomes insufficient based on the predicted power consumption of the web conference and the remaining capacity of battery 13. In order to ensure that the minimum internal operation of electronic apparatus 10 can be performed, controller 11 may determine that the remaining capacity of battery 13 is insufficient when the remaining capacity of battery 13 becomes less than a specific remaining capacity threshold. The remaining capacity threshold may be, for example, 3%, 5%, 10%, 15%, or 20%.

In a case where a schedule of one web conference is registered on the scheduled day, when determining that the remaining capacity of battery 13 becomes less than the remaining capacity threshold after the web conference, controller 11 determines that the drivable time of battery 13 is insufficient. In addition, in a case where the remaining capacity of battery 13 before performing the web conference is equal to or more than the remaining capacity threshold, it is determined that the timing at which the remaining capacity becomes insufficient is during the web conference.

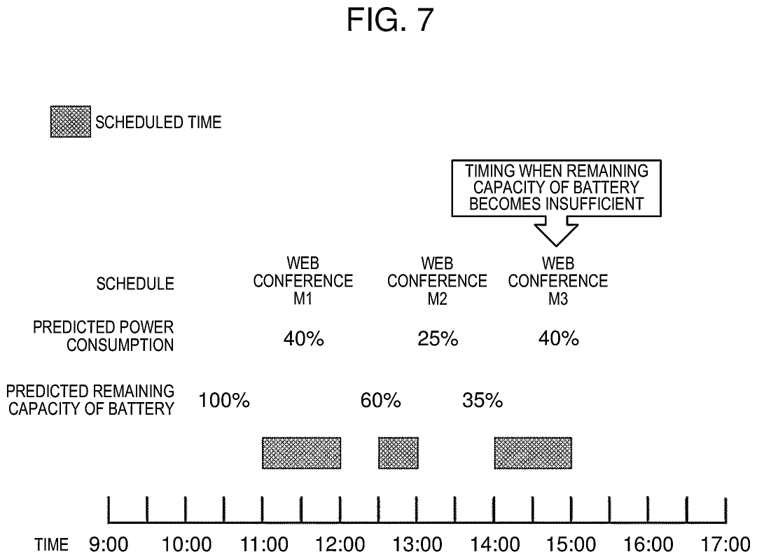

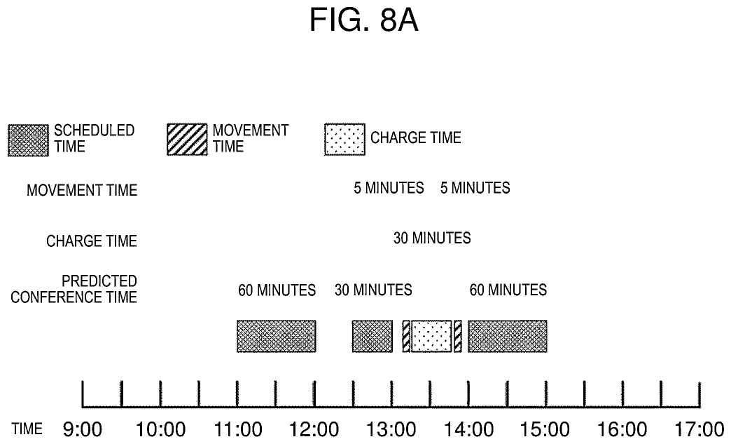

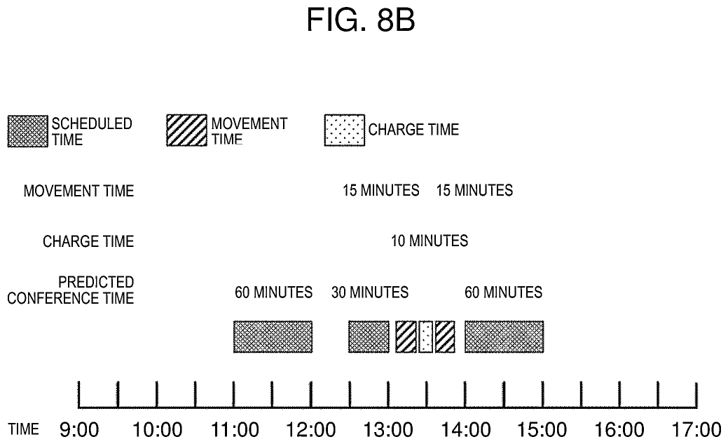

FIG. 7 is an example of timing at which the remaining capacity of battery 13 becomes insufficient in the second exemplary embodiment. In the examples illustrated in FIG. 7 to FIG. 8B, only the schedule of the web conference is registered in the schedule, but as will be described later, a schedule other than the web conference can be registered in the schedule. By setting the date on which the schedule of the web conference is not registered as “a scheduled date”, controller 11 can also determine the movement schedule for the scheduled date.

In the example of FIG. 7, assuming that, on the scheduled date, three schedules of web conference M1, web conference M2, and a web conference M3 are registered, and the first remaining capacity of battery 13 is 100%. Controller 11 determines that the scheduled time (predicted conference time) of each of web conferences M1 to M3 is 60 minutes, 30 minutes, and 60 minutes, and calculates each predicted power consumption to be 40%, 25%, and 40%. Therefore, it is determined that the remaining capacity of battery 13becomes 60% after web conference M1 and becomes 35% after web conference M2, and becomes insufficient during web conference M3. That is, the timing when the remaining capacity of battery 13 becomes insufficient is during web conference M3. In this manner, controller 11 can determine the timing when the remaining capacity of battery 13 becomes insufficient by comparing the remaining capacity with the predicted power consumption arranged in chronological order.

In addition, controller 11 also determines charging power for charging insufficient power. Predictively, the remaining capacity becomes 35% after web conference M2. However, before web conference M3, if the battery is charged up to a total of 50% of the predicted power consumption of 40% and the remaining capacity threshold (assumed to be 10%), the remaining capacity of battery 13 does not become insufficient. Therefore, the insufficient power is 40%+10%-35%=15%. Controller 11 can further determine charge time for charging the insufficient power. For example, if the rated power is used, it can be determined that it takes 15 minutes to charge a remaining capacity of 15%. In case of charging with power less than the rated power, it is possible to calculate the power to be charged from the remaining capacity of battery 13 and then determine the charge time with the power to be used.

In a case where it is determined that the drivable time of battery 13 becomes insufficient (YES in step S230), controller 11 acquires the visiting place, the movement time to the visiting place, and the area information of the visiting place based on the schedule (step S240). Controller 11 may determine the visiting place based on a conference place or a place registered in the schedule. In addition, controller 11 may acquire the address or area of the visiting place by searching for the place on the Internet. For example, controller 11 can specify the address and a location area of a conference place by searching for a company name of another company which is the conference place where the user goes out.

Here, the visiting place may be a geographical area, and the area may be, for example, a circular area having a radius of a predetermined distance around the visiting place. The predetermined distance may be a distance that the user can travel on foot, and may be, for example, 300 meters, 500 meters, 1000 meters, or 1500 meters. In addition, the area may be an administrative area where the visiting place is located, and for example, the visiting place may be located in a ward, a town, or a village.

Controller 11 may acquire the area information of the area of the visiting place via the Internet, server 30, or a specific application. The area information includes a place where electronic apparatus 10 can be charged in the area. The chargeable place refers to a place where the user is permitted to charge electronic apparatus 10 using the power and outlet of the place. The area information may include a name and an address of the chargeable place. In addition, the area information may further include the number of seats that can be provided at the chargeable place, a congestion status, providable rated power, availability of an adapter, and the like.

Then, based on the name or address of the visiting place, the movement time to the visiting place can be acquired via the Internet, server 30, or a specific application. For example, it is possible to acquire the movement time from the user's company to the conference place where web conference M1 is held via Google Map.

Controller 11 determines the movement schedule including a chargeable place and charge time based on the acquired area information, the movement time, and the charge time for charging insufficient power (step S250). Controller 11 acquires the area information of an area in which a place registered in a timing at which the remaining capacity becomes insufficient or before the timing is located, and specifies a chargeable place in the area. Controller 11 can determine the movement schedule so as to incorporate, into the movement schedule, charging at the chargeable place before the timing when the remaining capacity becomes insufficient. Furthermore, controller 11 may acquire the movement time from the place scheduled before charging to the chargeable place and the movement time from the chargeable place to the place scheduled next, and incorporate the acquired movement time into the movement schedule.

Note that, controller 11 can predict the power consumption due to other uses of electronic apparatus 10 as in a conventional manner. That is, controller 11 can determine predicted power consumption for a schedule other than the web conference by using the conventional technique. More specifically, one or more schedules using electronic apparatus 10 other than web conference may be registered in the schedule. For example, the use on the move in transportation such as trains or airplanes can be registered in the schedule or inferred from the place where the use is registered in the schedule. In addition, use for a presentation at a visit to a customer when going out or use in a lounge or a cafe when going out can also be registered in the schedule. In addition, since electronic apparatus 10 can be used even in a conference in which the conference application is not used (that is, an off-line conference that is not a web conference), a schedule of an off-line conference can be registered. Controller 11 can determine the predicted power consumption for these schedules using at least a part of the prior art and/or the technique of the present disclosure.

FIG. 8A is an example of the movement schedule in the second exemplary embodiment. The schedules other than the schedule originally registered in the schedule (web conferences M1 to M3), charging and moving for charging are also incorporated into the movement schedule. For example, in step S240, assuming that controller 11 acquires that there is a chargeable cafe near the conference place of web conference M3 and that it takes 5 minutes to move from the conference place of web conference M3 to the cafe. Then, based on the area information, since the power of the adapter provided by the cafe is lower than the rated power of electronic apparatus 10, it is determined that the charge time is 30 minutes. Therefore, the movement schedule illustrated in FIG. 8A includes three actions of moving from the conference place of web conference M3 to the cafe, charging in the cafe, and moving from the cafe to the conference place of web conference M3.

In one example, controller 11 determines the movement schedule by optimizing at least one movement schedule with respect to the movement distance for charging or the charge time. For example, in a case where there is a plurality of chargeable places in the area, controller 11 may select a chargeable place and determine the movement schedule so that the movement distance for charging is minimized in the daily schedule. On the other hand, in a case where the movement distance is short, but it is necessary to line up until charging can be performed in a congested manner, or in a place where the power to be provided is less than the rated power, the time required for charging is long. Controller 11 may select a chargeable place so that the time for charging is minimized in the daily schedule to determine the movement schedule.

FIG. 8B is another example of the movement schedule in the second exemplary embodiment. Assuming that it takes 15 minutes to move from the conference place of web conference M3 to the user's company, but the charge time can be shortened to 10 minutes because the charging can be performed at the rated power at the user's desk. That is, the movement schedule illustrated in FIG. 8A is a result optimized for the movement distance, and the movement schedule illustrated in FIG. 8B is a result optimized for the charge time. In a case where charging is performed a plurality of times in step S250, controller 11 may perform mathematical optimization on the movement schedule. In one example, controller 11 determines a plurality of movement schedules by performing mathematical optimization on each of the movement distance for charging and the charge time. The mathematical optimization is a method of defining an actual problem as a mathematical expression (mathematical model) and obtaining a value of a variable that minimizes a cost and maximizes a profit while satisfying constraint conditions. Here, the mathematical optimization refers to obtaining a suitable charging place, timing, and time so as to minimize the movement distance for charging or the charge time. Controller 11 may perform mathematical optimization by a well-known method such as a method based on differential integration, an iterative method that converges to an optimal solution, or linear programming.

In one example, controller 11 causes display 16 to display the determined movement schedule. Controller 11 may cause display 16 to display the chargeable place and the charge time together with the schedule. Alternatively, controller 11 may cause display 16 to display the chargeable place and the charge time as a notification message.

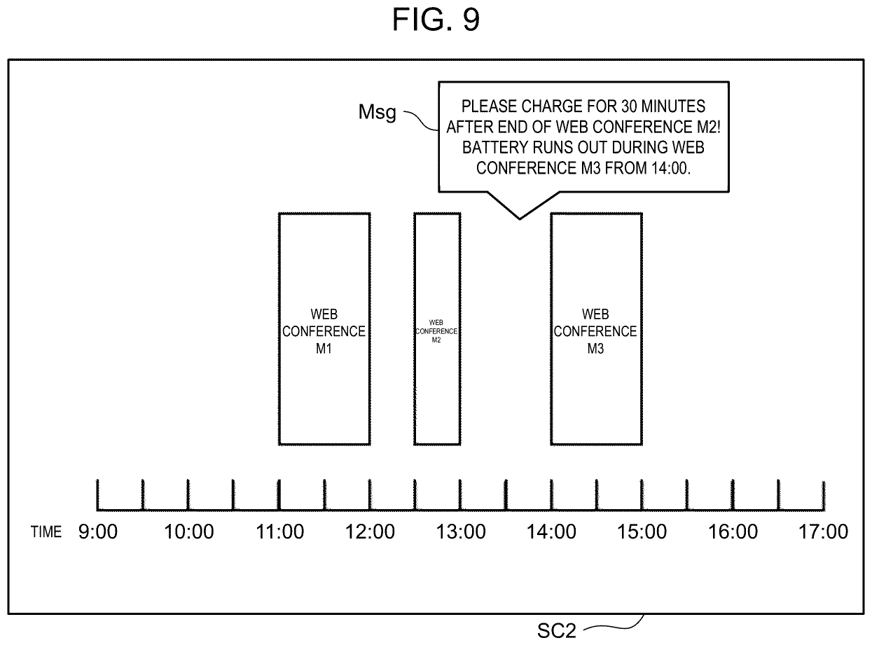

FIG. 9 is an example of the notification message in the second exemplary embodiment. Screen SC2 shows a schedule of the user. As described with reference to FIG. 7, if charging is not performed before web conference M3, it is determined that the remaining capacity of battery 13 becomes insufficient during the conference and electronic apparatus 10 cannot be used. Then, it is determined that a charge time of 30 minutes is required in a cafe where charging can be performed near the visiting place. Therefore, controller 11 prompts the user to charge by causing display 16 to display notification message Msg “Please charge for 30 minutes after end of web conference M2! Battery runs out during web conference M3 from 14:00.”.

In addition to the text message as illustrated in FIG. 9, the notification message may be a message in a format such as a pop-up message (push notification), a lock screen notification, a notification badge, or a notification banner.

In one example, in addition to charging and movement for charging, controller 11 can also propose “carrying an AC adapter” and “power saving mode switching”. For example, as a response to a case where battery 13 runs out before the end of the schedule even after charging, or a case where charging cannot be performed, controller 11 may propose switching to the power saving mode. In one example, controller 11 may propose by causing display 16 to display a notification message “The remaining capacity of the battery is insufficient, so switch to power saving mode.”.

As a result, the processing of determining the movement schedule related to charging is completed. In this way, in a case where the user is scheduled to go out and drivable time of battery 13 may be insufficient, it is possible to determine a chargeable place while the user is out and the charge time based on the area information and the like. Since the determination is made using the predicted power consumption calculated more accurately, it is possible to more accurately determine whether or not the drivable time of battery 13 becomes insufficient, when the drivable time is likely to become insufficient, and how much the remaining capacity is insufficient.

### Third Exemplary Embodiment

### <Display and Selection of Movement Schedule>

In the third exemplary embodiment, controller 11 can cause display 16 to display the movement schedule and the transition of the remaining capacity due to charging and discharging of battery 13 via the GUI. Looking at the transition of battery charging and discharging, the user can more intuitively understand the necessity of charging and the timing of charging.

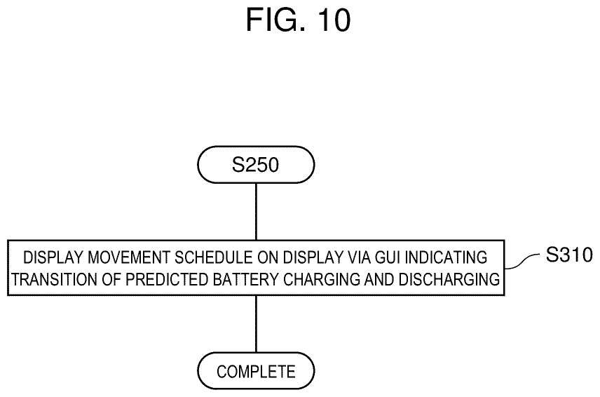

FIG. 10 is a flowchart of an example of a control method in the third exemplary embodiment. Since the movement schedule determined in the second exemplary embodiment is used, the processing described in the third exemplary embodiment may be performed after step S250 in FIG. 6. In the third exemplary embodiment, after determining the movement schedule in step S250, controller 11 causes display 16 to display the movement schedule via the GUI indicating the transition of the predicted battery charging and discharging (step S310). This GUI may be a GUI different from the schedule, may be a GUI that can transition from the schedule, or may be a GUI displayed together with the schedule.

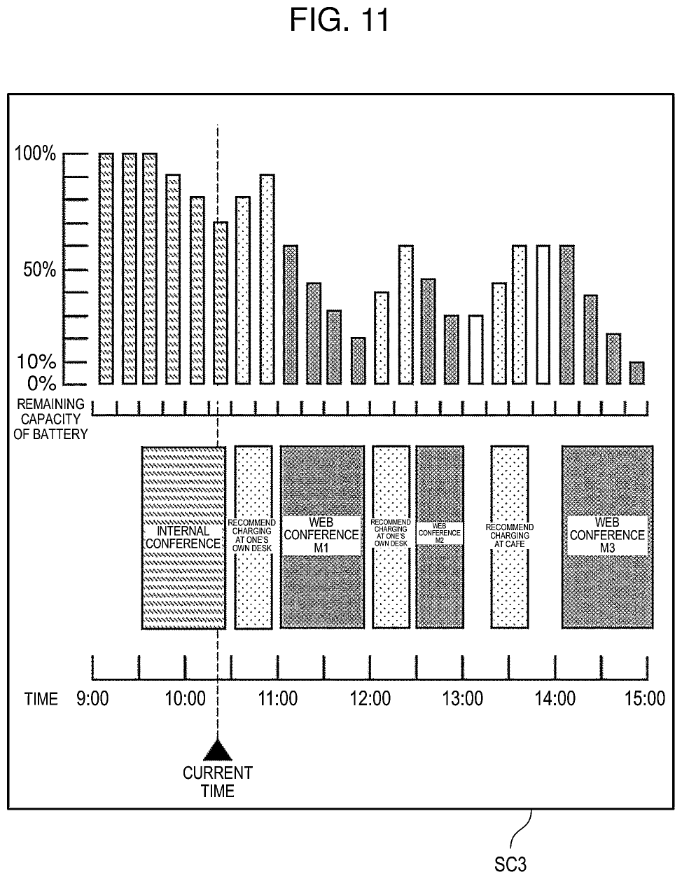

FIG. 11 is an example of the GUI in the third exemplary embodiment. The GUI shown on screen SC3 displays a charging and discharging transition of battery 13 and the movement schedule including a registered schedule and a proposal regarding charging. In this GUI, a horizontal axis is a time axis, a change (transition) in the remaining capacity of battery 13 according to charging and discharging is indicated in an upper portion, and a movement schedule is indicated in a lower portion. The remaining capacity of battery 13 decreases according to use of the web conference or the like, but increases according to charging. Note that, the numerical value indicated on the left side (earlier side in time) of the time axis than the “current time” is an actual measurement value of the remaining capacity of battery 13. On the other hand, the numerical value indicated on the right side of the time axis (later side in time) than the “current time” is a predicted value calculated by the method or the like described in the first exemplary embodiment.

Note that, the GUI illustrated in FIG. 11 is an example, and the displayable GUI is not limited thereto. For example, the charging and discharging transition of the remaining capacity of battery 13 may be represented as a line graph instead of a bar graph. In addition, all items of schedules may not be displayed in the movement schedule, and for example, when a mouse cursor is placed on a certain bar of the remaining capacity transition, the schedule corresponding to the bar may be displayed.

In one example, a remaining capacity threshold (for example, 10%) for ensuring that the minimum internal operation of electronic apparatus 10 can be performed is also displayed on the GUI. In addition, in order to keep the remaining capacity of battery 13 equal to or higher than the remaining capacity threshold, how much remaining capacity should be maintained in each schedule, that is, the remaining capacity of the minimum line in which battery 13 does not become insufficient can also be displayed on the GUI.

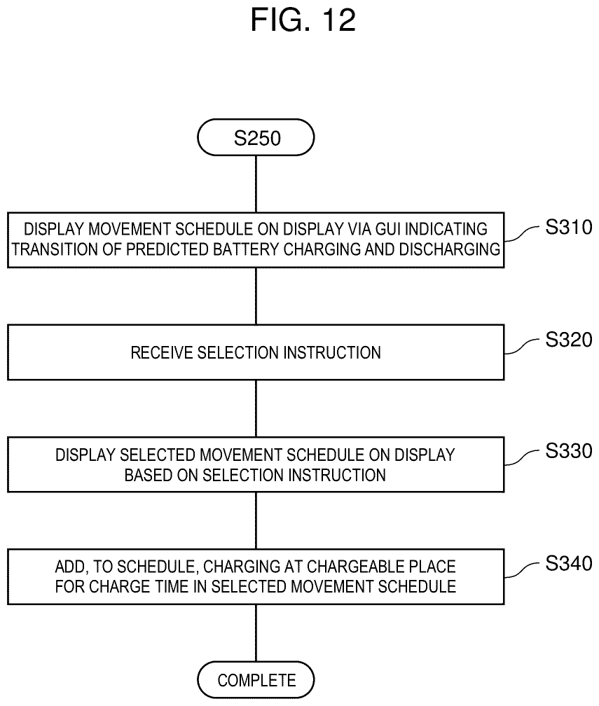

Controller 11 can present a plurality of movement schedules and then can automatically correct the schedule based on the movement schedule selected by the user. FIG. 12 is a flowchart of another example of a control method in the third exemplary embodiment. Since the movement schedule determined in the second exemplary embodiment is used, the processing described in the third exemplary embodiment may be performed after step S250 in FIG. 6.

Controller 11 causes display 16 to display the movement schedule via the GUI indicating the transition of the predicted battery charging and discharging (step S310). Controller 11 can present the plurality of movement schedules according to the optimization priority items (e.g. movement time or charge time). In a case where there is the plurality of movement schedules, the plurality of movement schedules may be displayed on the same screen. In addition, although one movement schedule is displayed, an icon for switching the plurality of movement schedules may be provided in the GUI.

Then, in a case where there is the plurality of movement schedules, controller 11 receives a selection instruction to select one of the plurality of movement schedules via input unit 15 (step S320). In one example, the GUI is provided with a check box corresponding to each movement schedule. When one of a plurality of check boxes is checked, that is, selected by the user, a selection instruction including the movement schedule corresponding to the checked box is transmitted to controller 11. In another example, one movement schedule is provided in the GUI together with an icon for switching the movement schedule and a confirm button of “select this schedule”. When the confirmation button is pressed, a selection instruction including the movement schedule (that is, the movement schedule displayed together with the confirmation button) corresponding to the confirmation button is transmitted to controller 11.

Upon receiving the selection instruction, controller 11 causes display 16 to display the selected movement schedule based on the selection instruction (step S330). In a case where display 16 originally displays the selected movement schedule, the same movement schedule may be continuously displayed. Then, controller 11 adds, to the schedule, charging at the chargeable place for charge time in the selected movement schedule (step S340). In this way, the user can easily recognize that charging should be performed and the timing from the schedule.

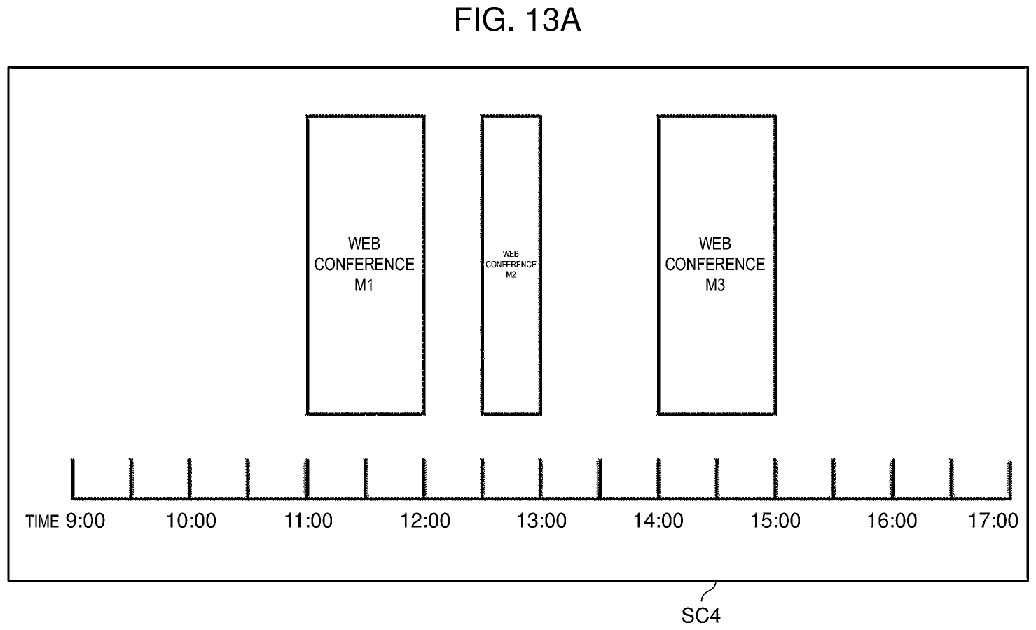

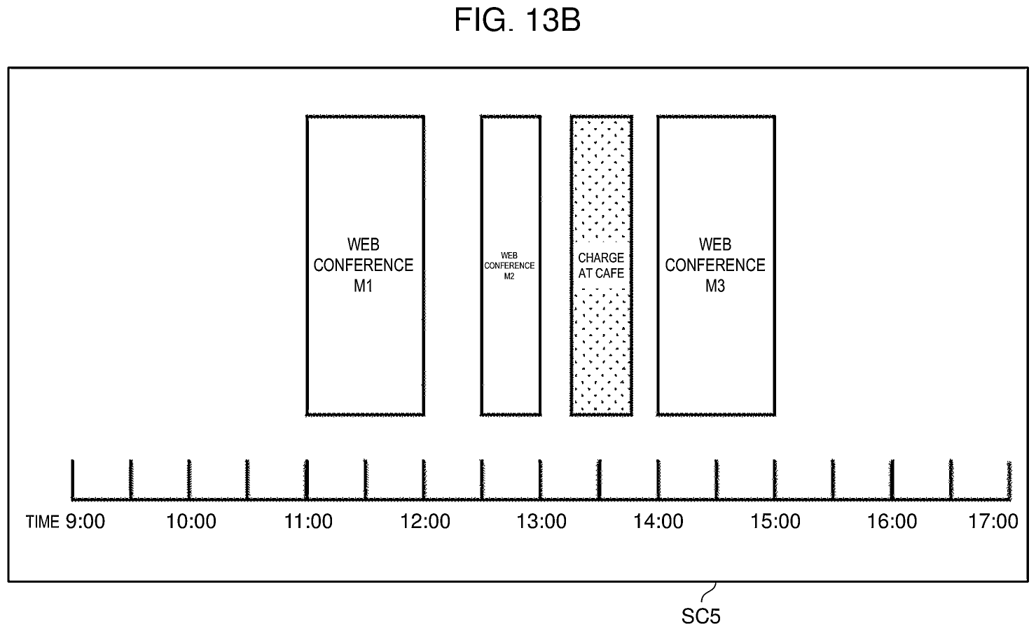

FIG. 13A is an example of a schedule before updating in the third exemplary embodiment, and FIG. 13B is an example of a schedule after updating in the third exemplary embodiment. In this example, a description will be given using an example of the same schedule as that in FIG. 7 to FIG. 9. The schedule includes schedules of web conferences M1 to M3 as in screen SC4 illustrated in FIG. 13A. Assuming that after controller 11 displays the movement schedules illustrated in FIG. 8A and FIG. 8B, the user selects the movement schedule in FIG. 8A. Based on the selection instruction, controller 11 sets charging in a cafe near web conference M3 as a new schedule and automatically adds the new schedule to the user's schedule as in screen SC5 illustrated in FIG. 13B. Controller 11 may register the charge time, the name and address of the chargeable place, the movement time to the place, or the moving route to the place described above in the schedule to be added. In this way, when checking the schedule, the user also can check the detailed information on charging.

As a result, the proposal of the movement schedule and the subsequent related processing are completed. By displaying the movement schedule and the prediction result on the charging and discharging transition of battery 13 together on the GUI, the user more intuitively understands the necessity of charging and the timing of charging, that is, this also urges the user to charge. In addition, controller 11 can propose the plurality of movement schedules to the user and cause the user to select a desired movement schedule. Furthermore, controller 11 can automatically add charging to the schedule by user's selection.

### Fourth Exemplary Embodiment

### <Charge Control for Battery Deterioration Prevention>

In a fourth exemplary embodiment, controller 11 performs charge control for preventing deterioration of battery 13. In a case where battery 13 is continuously charged with the fully charged state, there is a risk that the deterioration of battery 13 is accelerated by maintaining the fully charged state. In the charge control of the fourth exemplary embodiment, control is performed so as not to fully charge battery 13 as much as possible, except for a case where the remaining capacity may become insufficient later unless battery 13 is fully charged. Note that, the fully charged state refers to a state in which sufficient electric energy is stored in battery 13. For example, when the remaining capacity of new battery 13 that has not been deteriorated by use is charged to 100%, battery 13 is fully charged.

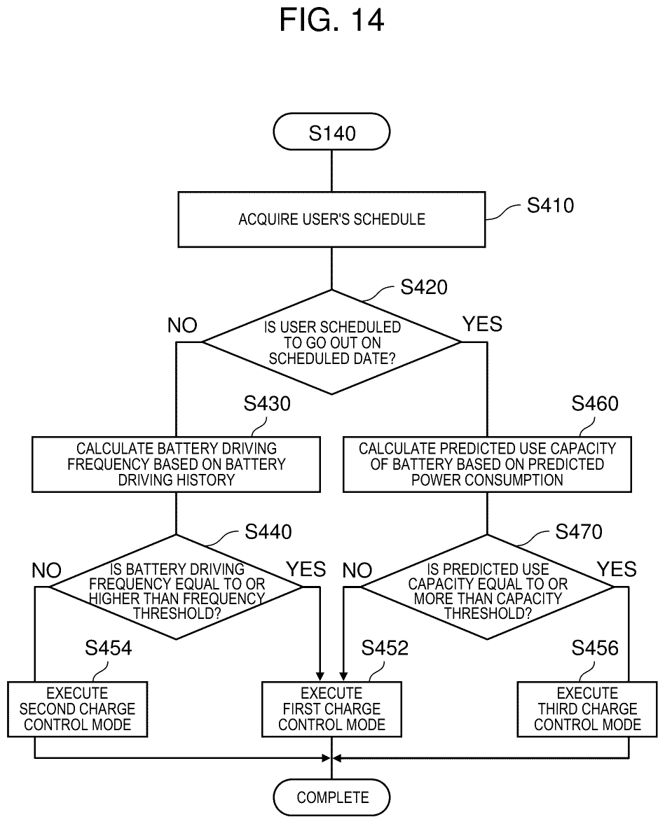

FIG. 14 is a flowchart of an example of a control method in the fourth exemplary embodiment. The processing described in the fourth exemplary embodiment may be performed after step S140 in FIG. 2 so as to use the predicted power consumption of the web conference and the change in the remaining capacity of battery 13.

First, controller 11 acquires a schedule of the user in which the schedule of the web conference is registered (step S410). For example, as in step S210 in FIG. 6, controller 11 acquires the schedule of the user by reading the schedule from storage 12 or downloading the schedule from the Internet. However, if the schedule has already been acquired in steps S110 to S140 in FIG. 2, step S410 here can be omitted.

Next, controller 11 determines, based on the schedule, whether or not the user is scheduled to go out on the date on which the schedule of the web conference is registered (that is, the scheduled date) (step S420). The determination of schedule of outing in step S420 is similar to that in step S220 in FIG. 6, and redundant description will be omitted here. Note that, as described above, a schedule other than the web conference can be registered in the schedule. Controller 11 can set the date on which the schedule of the web conference is not registered as “scheduled date” and perform the following control for the scheduled date.

In a case where it is determined that the user is not scheduled to go out (NO in step S420), controller 11 calculate the battery driving frequency based on the battery driving history (step S430). The battery driving history includes information on how battery 13 has been used to drive electronic apparatus 10 in the past. For example, the battery driving history may include information such as a date and time when electronic apparatus 10 is driven by battery 13, a change in the remaining capacity, or a connection status with external power supply 20. The battery driving frequency indicates how frequently electronic apparatus 10 is driven by battery 13 in a certain period. The certain period here may be, for example, 3 days, 1 week, 10 days, 2 weeks, or 1 month. Hereinafter, the battery driving frequency indicates how many times electronic apparatus 10 is driven by battery 13 per week. The battery driving frequency can be calculated from the statistical data of the battery driving history. For example, an average value, a median value, or the most frequent value of the number of days of driving by battery 13 in a week may be set as the battery driving frequency.

Next, the controller 11 determines whether or not the battery driving frequency is equal to or higher than the frequency threshold (step S440). The frequency threshold may be, for example, once a week, twice a week, or three times a week.

In a case where the battery driving frequency is equal to or higher than the frequency threshold (YES in step S440), controller 11 executes a first charge control mode so as to maintain the remaining capacity of battery 13 within a first range (step S452). The fact that the battery driving frequency is equal to or higher than the frequency threshold indicates that the battery driving frequency is relatively high and electronic apparatus 10 is often used in a state of not being connected to external power supply 20. In this case, if the remaining capacity is maintained in a relatively high range although battery 13 is not fully charged, it is possible to avoid shortage of the remaining capacity during driving of battery 13. Therefore, the first range is a range that is not fully charged and has a relatively high remaining capacity, and may be, for example, 60% to 80%, 70% to 85%, or 75% to 80%.

In a case where the battery driving frequency is less than the frequency threshold (NO in step S440), controller 11 executes a second charge control mode so as to maintain the remaining capacity of battery 13 within a second range (step S454). When the battery driving frequency is less than the frequency threshold, it is considered that electronic apparatus 10 is often used in a state of being connected to external power supply 20 and the usability of electronic apparatus 10 is not impaired even if the remaining capacity is maintained in a relatively low range. Therefore, the second range is a range that is not fully charged and has a relatively low remaining capacity, and may be, for example, 10% to 60%, 10% to 50%, or 20% to 50%. Note that, according to the experimental results, if the remaining capacity of battery 13 can be maintained in a relatively low range, the effect of reducing deterioration becomes more effective.

On the other hand, in a case where it is determined that the user is scheduled to go out (YES in step S420), the possibility that the remaining capacity becomes insufficient during driving of battery 13 is higher than that in a case where the user is not scheduled to go out. Therefore, when determining that the user is scheduled to go out, controller 11 calculates the predicted use capacity of battery 13 based on the predicted power consumption (step S460), and determines whether or not the predicted use capacity is equal to or more than the capacity threshold (step S470). For example, controller 11 may calculate the predicted use capacity based on the total value of the predicted power consumption of all the schedules at the time of going out. When the user is scheduled to go out, the user generally wants to keep the remaining capacity of battery 13 relatively high. The capacity threshold is a threshold for determining whether or not to execute charge control while maintaining a relatively high remaining capacity, and may be, for example, 75%, 80%, or 90%.

In a case where it is determined that the predicted use capacity is equal to or more than the capacity threshold (YES in step S470), it indicates that there is a high possibility that a large remaining capacity is used at the time of going out, and thus, it is considered that the remaining capacity should be maintained high even if battery 13 is somewhat likely to deteriorate. Therefore, in a case where it is determined that the predicted use capacity is equal to or more than the capacity threshold, controller 11 executes a third charge control mode so as to maintain the remaining capacity of battery 13 within a third range (step S456). The third range is a relatively high range. In one example, the third range may be, for example, 90% or more, 95% or more, or 98% or more. In this way, battery 13 can be prevented from deteriorating by not being fully charged. In another example, in a case where it is determined that the predicted use capacity is equal to or more than the capacity threshold, controller 11 fully charges battery 13.

In a case where it is determined that the predicted use capacity is less than the capacity threshold (NO in step S470), it indicates that the possibility that a large remaining capacity is used at the time of going out is not relatively high, and thus it is considered that the remaining capacity should be maintained high while preventing battery 13 from deteriorating. Therefore, in a case where it is determined that the predicted use capacity is less than the capacity threshold, controller 11 executes the first charge control mode so as to maintain the remaining capacity of battery 13 within the first range (step S452).

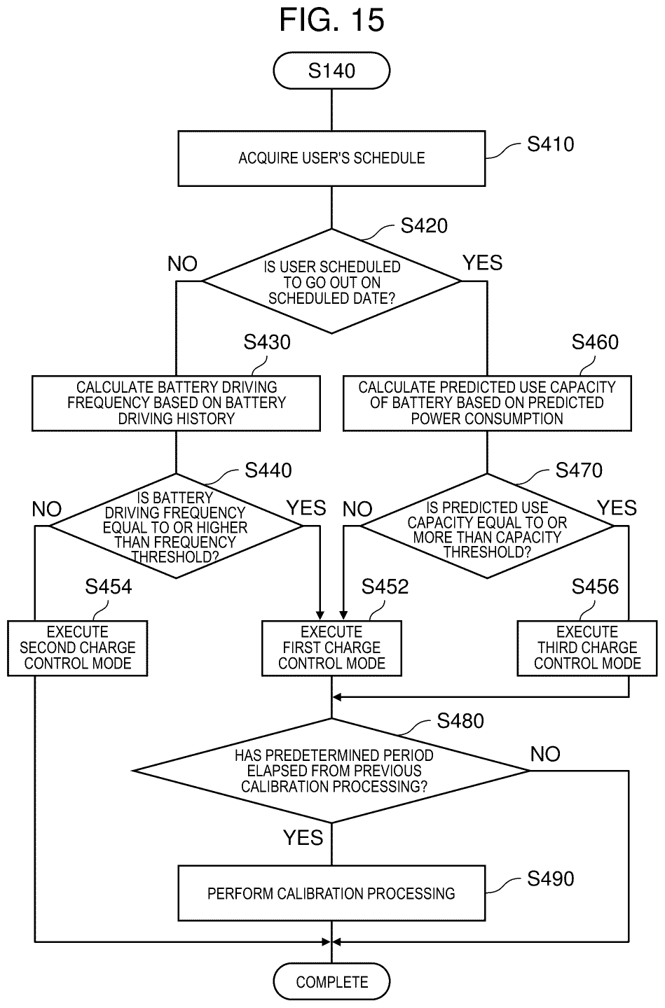

In one example, in order to accurately measure the remaining capacity of battery 13 and accurately predict charge and discharge time, controller 11 periodically performs a calibration processing. FIG. 15 is a flowchart of another example of a control method in the fourth exemplary embodiment. After executing the first charge control mode, the second charge control mode, or the third charge control mode described above, controller 11 determines whether or not a predetermined period has elapsed from the previous calibration processing (step S480). Here, the predetermined period refers to an interval of time for performing the calibration processing, and may be, for example, one month, three months, four months, six months, or one year. In a case where it is determined that the predetermined period has already elapsed since the previous calibration processing (YES in step S480), controller 11 performs the calibration processing (step S490).

In the calibration processing, controller 11 once uses up the remaining capacity of battery 13 to 0%, and then charges the remaining capacity of battery 13 from 0% to full charge. In one example, in the calibration processing, controller 11 may repeat charging of battery 13 from 0% to full charge a plurality of times. The calibration processing calibrates the measurement and display of the remaining capacity of battery 13.

As a result, the charge control for preventing deterioration of battery 13 is completed. By not fully charging battery 13 as much as possible, deterioration of battery 13 can be reduced. Since controller 11 determines the charging mode based on whether or not the user is scheduled to go out, the battery driving frequency, or the predicted use capacity, the user can use the electronic apparatus without anxiety even when going out without forcibly maintaining the remaining capacity low. In addition, since the predicted power consumption calculated more accurately is used, it is possible to more accurately determine whether or not the remaining capacity of the battery is sufficient when going out. Furthermore, by periodically performing the calibration processing, it is possible to accurately measure the remaining capacity of battery 13 and accurately predict the charge and discharge time.

### Fifth Exemplary Embodiment

<Power Supply Control to Component of Electronic Apparatus>

In a fifth exemplary embodiment, power supply control is performed when electronic apparatus 10 is connected to external power supply 20 that is less than the rated power. According to the power supply control, power can be appropriately fed to a component of electronic apparatus 10. In addition, in a case where power reduction due to less than the rated power occurs, power reduction control can be appropriately performed.

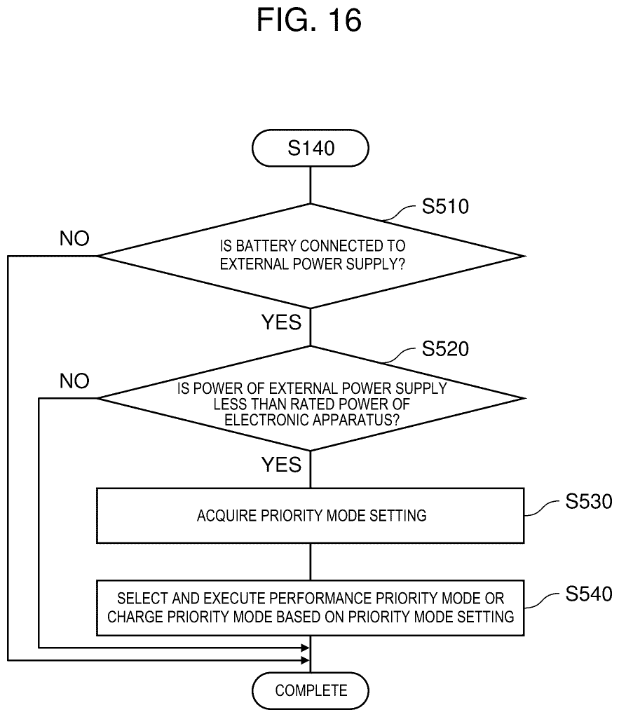

FIG. 16 is a flowchart of an example of a control method in the fifth exemplary embodiment. The processing described in the fifth exemplary embodiment may be performed after step S140 in FIG. 2 so as to use the predicted power consumption of the web conference and the change in the remaining capacity of battery 13.

First, controller 11 determines whether or not battery 13 is connected to external power supply 20 (step S510). When determining that battery 13 is connected to external power supply 20 (YES in step S510), controller 11 further determines whether or not the power of external power supply 20 (hereinafter, it may be abbreviated as external power) is less than the rated power of electronic apparatus 10 (step S520). In a case where battery 13 is not connected to external power supply 20 (NO in step S510) or in a case where the external power is equal to or higher than the rated power (NO in step S520), the power supply control in the fifth exemplary embodiment may not be performed.

In a case where it is determined that the power of external power supply 20 is less than the rated power of electronic apparatus 10 (YES in step S520), controller 11 acquires a priority mode setting (step S530). As described above, in a case where battery 13 is connected to external power supply 20, the sum of power supplied from external power supply 20 to electronic apparatus 10 and power charged from external power supply 20 to battery 13 is constant. External power supply 20 supplies power for charging battery 13 with surplus power of power supplied as power consumption of electronic apparatus 10. The priority mode setting is a setting that defines a reference of power supply control, and may define, for example, at what rate limited external power is supplied to battery 13. The priority mode setting may be input in advance by the user or may be automatically set by electronic apparatus 10. The priority mode setting may be stored in storage 12 of electronic apparatus 10, and controller 11 can acquire the priority mode setting by reading the priority mode setting from storage 12.

In one example, the priority mode setting is a setting for designating a performance priority mode or a setting for designating a charge priority mode. Controller 11 selects and executes the performance priority mode or the charge priority mode based on the acquired priority mode setting (step S540).

In the performance priority mode, external power supply 20 preferentially supplies power to the CPU so that the performance of the CPU of electronic apparatus 10 does not deteriorate. The performance of electronic apparatus 10 is greatly affected by the CPU. When the power supply becomes insufficient, the CPU cannot sufficiently exert the performance, and the overall performance of electronic apparatus 10 decreases accordingly. Therefore, in the performance priority mode, power is preferentially supplied to the CPU in order to secure the performance of electronic apparatus 10. Note that, the CPU may be controller 11, or may be a controller or a processor different from controller 11.

In the charge priority mode, external power supply 20 preferentially supplies power to battery 13. In the charge priority mode, priority is given to charging battery 13 while suppressing power for moving electronic apparatus 10.

In step S540, controller 11 executes the performance priority mode or the charge priority mode. However, since the external power is less than the rated power, for example, even if the performance priority mode is executed, there is a possibility that the power supplied to the CPU decreases. Similarly, even if the charge priority mode is executed, there is a possibility that the power supplied to battery 13 decreases. In such a case, controller 11 may perform the power reduction control as follows.

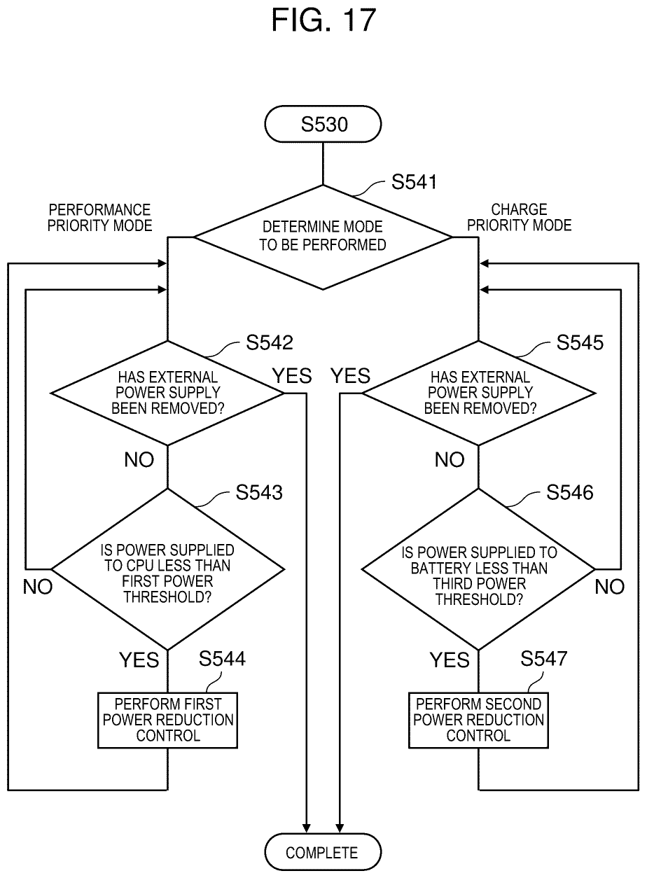

FIG. 17 is a flowchart of an example of step S540 in the fifth exemplary embodiment. First, as described above, controller 11 determines the mode to be performed based on the priority mode setting (step S541). That is, controller 11 selects and executes the performance priority mode or the charge priority mode. In any priority mode, controller 11 monitors and determines whether external power supply 20 has been removed from electronic apparatus 10 (Step S542 and Step S545). When external power supply 20 is removed, the power supply control and the power reduction control of the fifth exemplary embodiment may be ended.

When it is determined that external power supply 20 has not been removed in the performance priority mode (NO in step S542), controller 11 determines whether or not the power supplied to the CPU is less than the first power threshold (step S543). That is, controller 11 determines whether or not the power supplied to the CPU has decreased. In a case where it is determined that the power supplied to the CPU has been less than the first power threshold (YES in step S543), controller 11 performs the first power reduction control (step S544).

In the first power reduction control, controller 11 may perform the following items so as to reduce the power consumption of electronic apparatus 10. First, controller 11 may change the power supply option of the OS of electronic apparatus 10. For example, in a case where electronic apparatus 10 executes the OS of Microsoft Windows (registered trademark), the setting may be changed so as to activate the “power saving” function. Next, controller 11 may stop power supply to input unit 15 or connection port 18 of electronic apparatus 10. For example, when specific input unit 15 or connection port 18 is not used, power consumption can be reduced by stopping the power supply to input unit 15 or connection port 18. Next, controller 11 may stop the power supply to the component whose power consumption is equal to or greater than the second power threshold in electronic apparatus 10, or stop the power supply to battery 13. That is, controller 11 may stop the power supply to battery 13 or the component having relatively high power consumption.

In one example, the items of the first power reduction control described above are sequentially performed so as to gradually reduce the power consumption of electronic apparatus 10. In another example, controller 11 performs a plurality of stages (items of reduction control) together so as to more effectively reduce the power consumption.

When it is determined that external power supply 20 has not been removed in the charge priority mode (NO in step S545), controller 11 determines whether or not the power supplied to battery 13 is less than the third power threshold (step S546). That is, controller 11 determines whether or not the power supplied to battery 13 has decreased. In a case where it is determined that the power supplied to battery 13 is less than the third power threshold (YES in step S546), controller 11 performs the second power reduction control (step S547).

In the second power reduction control, controller 11 may perform the following items so as to reduce the power consumption of electronic apparatus 10. As described above, controller 11 may change the power supply option of the OS of electronic apparatus 10 and stop the power supply to input unit 15 or connection port 18 of electronic apparatus 10. Then, controller 11 may stop the power supply to the component whose power consumption is equal to or greater than the second power threshold in electronic apparatus 10, or may limit the power to the CPU. That is, controller 11 may stop the power supply to the component having relatively high power consumption, or may reduce the power supply to the CPU by limiting the performance of the CPU.

In one example, the items of the second power reduction control described above are sequentially performed so as to gradually reduce the power consumption of electronic apparatus 10. In another example, controller 11 performs a plurality of stages (items of reduction control) at the same time so as to more effectively reduce the power consumption.

Note that, the power supply control and the power reduction control of the fifth exemplary embodiment can be executed by a basic input output system (BIOS), an embedded controller (EC), a power supply microcomputer (power micro-computer or power micro-controller), a battery micro-computer (battery micro-computer or battery micro-controller), or the OS of electronic apparatus 10.

As a result, the power supply control or the power reduction control of electronic apparatus 10 is completed. According to such control, for example, in case where the user uses an adapter that becomes less than the rated power when going out, controller 11 can appropriately supply limited external power to the component of electronic apparatus 10. In addition, in a case where power reduction due to less than the rated power occurs, power reduction control can be appropriately performed. For example, it is possible to more accurately determine whether or not to change the power supply option of the OS of the electronic apparatus.

Note that, the present disclosure also provides a computer program and a storage medium for a control method for controlling electronic apparatus 10, which corresponds to the second exemplary embodiment to the fifth exemplary embodiment.

The above embodiments are merely specific exemplary embodiments of the present disclosure, and the protection scope of the present disclosure is not limited thereto. The present disclosure includes the content described above in the drawings and the specific exemplary embodiments described above, but the present disclosure is not limited to the contents. Various disclosed exemplary embodiments or examples can be combined without departing from the scope or spirit of the present disclosure. Changes that do not depart from functional and structural principles of the present disclosure are within the scope of the claims.

### REFERENCE MARKS IN THE DRAWINGS

10: electronic apparatus
11: controller
12: storage
13: battery
14: communication unit
15: input unit
16: display
17: camera
18: connection port
20: external power supply
30: server
SC1 to SC5: screen
I1 to I7: item
M1 to M3: web conference
Msg: notification message

1. An electronic apparatus comprising:
a controller;
a storage that stores an instruction executed by the controller; and
a battery that supplies power to the controller and the storage;
wherein the controller:
acquires conference information related to a web conference, and the conference information includes information for specifying an application used in the web conference, conference date and time of the web conference, and information related to a conference place or a conference participant;
determines, based on the acquired conference information, information related to a use function or a use apparatus used in an application of the web conference;
calculates, based on the determined information related to the use function or the use apparatus, predicted power consumption consumed in the web conference; and
calculates, based on the calculated predicted power consumption and remaining capacity of the battery, a change in the remaining capacity of the battery.

2. The electronic apparatus according to claim 1,
wherein the controller acquires at least a part of the conference information from a schedule of a user in which a schedule of the web conference is registered, from a guide mail of the web conference, or from a user input.

3. The electronic apparatus according to claim 1,
wherein the conference information includes at least one of the information for specifying the application used in the web conference, a conference title, a conference type, the conference date and time, the conference place, the conference participant, and a conference organizer.

4. The electronic apparatus according to claim 1,
wherein the information related to the use function includes at least one of the web conference application, charging availability of the conference place, necessity of use of background blurring, necessity of use of a virtual background, and necessity of use of screen sharing.

5. The electronic apparatus according to claim 1,
wherein the information related to the use apparatus includes at least one of a communication environment of the conference place, screen luminance, necessity of use of a camera, necessity of use of Bluetooth apparatus, necessity of use of a USB apparatus, and charging availability of the conference place.

6. The electronic apparatus according to claim 1,
wherein the information for specifying the application used in the web conference includes a link of the web conference, and
the controller:
specifies, based on the link, the application of the web conference; and
determines, based on the specified application, base power consumption being power that is consumed by using the application.

7. The electronic apparatus according to claim 6,
wherein the storage stores a comparison table of information related to the use function or the use apparatus of the web conference and optional power consumption corresponding to the use function or the use apparatus, the optional power consumption is power that is consumed by using the use function or the use of the use apparatus, and
the controller determines the optional power consumption corresponding to the determined information related to the use function or the use apparatus based on the comparison table.

8. The electronic apparatus according to claim 7,
wherein the base power consumption is set based on a history of actual power consumption by the application, and
the optional power consumption in the comparison table is set based on a history of actual power consumption by each piece of the information related to the use function or the use apparatus.

9. The electronic apparatus according to claim 7,
wherein the controller:
determines, based on the acquired conference information, predicted conference time related to time when the web conference is held; and
calculates predicted power consumption of the web conference based on the base power consumption, the optional power consumption, and the predicted conference time.

10. The electronic apparatus according to claim 9,
wherein the base power consumption and the optional power consumption are power consumption within unit time and
the predicted power consumption of the web conference is calculated by multiplying the predicted conference time by a total value of the base power consumption and the optional power consumption.

11. The electronic apparatus according to claim 1,
wherein the controller:
acquires a schedule of a user in which a schedule of the web conference is registered;
determines, based on the schedule, whether or not the user is scheduled to go out on a day on which the web conference is registered;
in a case where it is determined that the user is scheduled to go out, determines whether or not a drivable time of the battery becomes insufficient based on the predicted power consumption and the remaining capacity of the battery,
in a case where it is determined that the drivable time of the battery becomes insufficient,
acquires a visiting place, movement time to the visiting place, and area information of the visiting place based on the schedule; and
determines at least one movement schedule including a chargeable place and charge time based on the area information, the movement time, and the charging time for charging insufficient power; and
the area information includes information related to the chargeable place.

12. The electronic apparatus according to claim 11,
wherein in a case where the controller determines that the user is scheduled to go out, the controller:
calculates predicted power consumption of one or more web conferences registered on a day on which it is determined that the user is scheduled to go out; and
compares the remaining capacity of the battery with the predicted power consumption of the one or more web conferences to determine whether or not the battery drivable time becomes insufficient;
in a case where the controller determines that the drivable time of the battery becomes insufficient,
determines a timing at which the remaining capacity of the battery becomes insufficient and charging power for charging insufficient power based on the predicted power consumption of the one or more web conferences and the remaining capacity of the battery;
determines the charge time based on the charging power; and
determines the at least one movement schedule based on the area information, the charge time, and the timing of becoming insufficient.

13. The electronic apparatus according to claim 11,
wherein the controller determines the at least one movement schedule by optimizing the at least one movement schedule with respect to a movement distance for charging or the charge time.

14. The electronic apparatus according to claim 11, the electronic apparatus further comprising a display,
wherein the controller:
causes the display to display the at least one movement schedule; and
causes the display to display the chargeable place and the charge time together with the schedule; or
causes the display to display the chargeable place and the charge time as a notification message.

15. The electronic apparatus according to claim 14,
wherein the controller causes the display to display the movement schedule via a graphical user interface (GUI) indicating transition of predicted battery charging and discharging, and
the GUI further indicates at least one of a title of the web conference, the conference place, the conference date and time, the chargeable place, and the charge time.

16. The electronic apparatus according to claim 15, the electronic apparatus further comprising an input unit,
wherein the controller:
in a case where the at least one movement schedule is a plurality of movement schedules, receives, via the input unit, a selection instruction to select one of the plurality of movement schedules; and
causes the display to display the selected movement schedule based on the selection instruction.

17. The electronic apparatus according to claim 16,
wherein the controller adds charging at the chargeable place for the charge time in the selected movement schedule to the schedule.

18. The electronic apparatus according to claim 1,
wherein the storage stores a battery driving history that records that the electronic apparatus is driven by the battery, and
the controller:
acquires a schedule of a user in which a schedule of the web conference is registered;
determines, based on the schedule, whether or not the user is scheduled to go out on a day on which the web conference is registered;
in a case where it is determined that the user is not scheduled to go out,
calculates a battery driving frequency based on a battery driving history; and
in a case where the battery driving frequency is equal to or higher than a frequency threshold, executes a first charge control mode so that the remaining capacity of the battery is maintained within a first range.

19. The electronic apparatus according to claim 18,
wherein in a case where the battery driving frequency is less than the frequency threshold, the controller executes a second charge control mode so that the remaining capacity of the battery is maintained within a second range, and
the second range is lower than the first range.

20. The electronic apparatus according to claim 18,
wherein the controller:
in a case where it is determined that the user is scheduled to go out,
calculates a predicted use capacity of the battery based on the predicted power consumption;
determines whether or not the predicted use capacity is equal to or more than a capacity threshold; and
in case of determining that the predicted use capacity is equal to or more than the capacity threshold, executes a third charge control mode so as to maintain the remaining capacity of the battery within a third range; and
the third range is higher than the first range.

21. The electronic apparatus according to claim 20,
wherein the controller,
in case of determining that the predicted use capacity is less than the capacity threshold, executes the first charge control mode so as to maintain the remaining capacity of the battery within the first range.

22. The electronic apparatus according to claim 18,
wherein the controller:
calculates a predicted use capacity of the battery based on the predicted power consumption; and
periodically performs a calibration processing of charging the battery after setting the remaining capacity of the battery to 0% based on the predicted use capacity.

23. The electronic apparatus according to claim 1,
wherein the controller:
determines whether or not the battery is connected to an external power supply;
determines whether or not power of the external power supply is less than rated power of the electronic apparatus when determining that the battery is connected to the external power supply; and
acquires a priority mode setting in case of determining that power of the external power supply is less than rated power of the electronic apparatus; and
selects and executes, based on the priority mode setting, a performance priority mode for preferentially supplying power to a central processing unit (CPU) of the electronic apparatus so that performance of the CPU is not degraded or a charge priority mode for preferentially supplying power to the battery.

24. The electronic apparatus according to claim 23,
wherein in the performance priority mode,
in a case where it is determined that power supplied to the CPU is less than a first power threshold, in order to reduce power consumption of the electronic apparatus, the controller changes a power supply option of an operating system (OS) of the electronic apparatus, stops power supply to an input unit or a connection port of the electronic apparatus, stops power supply to a component whose power consumption is equal to or more than a second power threshold in the electronic apparatus, or stops power supply to the battery.

25. The electronic apparatus according to claim 23,
wherein in the charge priority mode,
in a case where it is determined that power supplied to the battery is less than a third power threshold, in order to reduce power consumption of the electronic apparatus, the controller changes a power supply option of an operating system (OS) of the electronic apparatus, stops power supply to an input unit or a connection port of the electronic apparatus, stops power supply to a component whose power consumption is equal to or more than a second power threshold in the electronic apparatus, or limits power to the CPU.

26. A control method for controlling an electronic apparatus including a battery, the control method comprising:
acquiring conference information related to a web conference, wherein the conference information includes information for specifying an application used in the web conference, a conference date and time of the web conference, and information related to a conference place or a conference participant; and
determining information related to a use function or a use apparatus used in an application of the web conference based on the acquired conference information;
calculating predicted power consumption consumed in the web conference based on the determined information related to the use function or the use apparatus; and
calculating a change in remaining capacity of the battery based on the calculated predicted power consumption and the remaining capacity of the battery.

27. A computer program is a computer program for causing an electronic apparatus to execute the control method according to claim 26.

28. A non-transitory computer-readable storage medium storing a computer program,
the non-transitory computer-readable storage medium that implements the control method according to claim 26 when the computer program is executed by a processor.
